(19) United States
(12) Patent Application Publication
(10) Pub. No.: US 2026/0031030 A1
(43) Pub. Date: Jan. 29, 2026

(54) DISPLAY PANEL AND ELECTRONIC DEVICE INCLUDING THE DISPLAY PANEL

(71) Applicant: Samsung Display Co., Ltd., Yongin-si (KR)

(72) Inventors: Wonse Lee, Yongin-si (KR); Minkyung Park, Yongin-si (KR); Donghyeon Jang, Yongin-si (KR); Minhee Choi, Yongin-si (KR)

(21) Appl. No.: 19/282,147

(22) Filed: Jul. 28, 2025

(30) Foreign Application Priority Data
Jul. 29, 2024 (KR) 10-2024-0100544

(51) Int. Cl. G09G 3/32; G09G 3/3233; H10H 29/37; H10H 29/39; H10H 29/49; H10K 59/121; H10K 59/122; H10K 59/131

(52) U.S. Cl. CPC G09G 3/32; G09G 3/3233; H10H 29/37; H10H 29/39; H10H 29/49; H10K 59/1213; H10K 59/1216; H10K 59/122; H10K 59/131; G09G 2300/0819; G09G 2320/066; G09G 2330/021

(57) ABSTRACT

A display panel includes a pixel defining layer including a first pixel opening defining a first light-emitting area of a first light-emitting element, a second pixel opening defining a second light-emitting area of a second light-emitting element, a third pixel opening defining a third light-emitting area of the third light-emitting element, and an opening defining a hole area, wherein the hole area is spaced apart from circuit elements constituting first to third pixel circuits, wires electrically connected to the first to third pixel circuits, and in a plan view, a center of the hole area is located within an imaginary triangle defined by connecting a center of the first light-emitting area, a center of the second light-emitting area, and a center of the third light-emitting area.

### CROSS-REFERENCE TO RELATED APPLICATION

The present application claims priority to and the benefit of Korean Patent Application No. 10-2024-0100544, filed on Jul. 29, 2024, in the Korean Intellectual Property Office, the entire disclosure of which is incorporated herein by reference.

### BACKGROUND

### 1. Field

Aspects of some embodiments relate to a display panel and an electronic device including the same.

### 2. Description of the Related Art

In recent years, electronic devices that include display panels have become more diverse in their uses. In addition, as electronic devices have become thinner and lighter, the range of applications for electronic devices is expanding. As electronic devices including display panels may be utilized in various fields, there may be various methods for designing display panels.

The above information disclosed in this Background section is only for enhancement of understanding of the background and therefore the information discussed in this Background section does not necessarily constitute prior art.

### SUMMARY

Aspects of some embodiments include a display panel having secured transmittance in a region where a component is arranged, and an electronic device including the display panel. However, the embodiments are just examples and do not limit the scope of embodiments according to the present disclosure.

Additional aspects will be set forth in part in the description which follows and, in part, will be apparent from the description, or may be learned by practice of the presented embodiments of the disclosure.

According to some embodiments of the present disclosure, a display panel includes a first pixel circuit, a second pixel circuit, and a third pixel circuit each including a driving transistor and a capacitor on a substrate, and arranged along a first direction, a first light-emitting element, a second light-emitting element, and a third light-emitting element, electrically connected to the first pixel circuit, the second pixel circuit, and the third pixel circuit, respectively, and a pixel defining layer including a first pixel opening defining a first light-emitting area of the first light-emitting element, a second pixel opening defining a second light-emitting area of the second light-emitting element, a third pixel opening defining a third light-emitting area of the third light-emitting element, and an opening defining a hole area, wherein, in a plan view, the first light-emitting area and the second light-emitting area may be arranged along a second direction perpendicular to the first direction, and the third light-emitting area may be arranged along the first direction from each of the first light-emitting area and the second light-emitting area, wherein, in a plan view, the hole area may be arranged spaced apart from circuit elements constituting the first pixel circuit, wires electrically connected to the first pixel circuit, circuit elements constituting the second pixel circuit, wires electrically connected to the second pixel circuit, circuit elements constituting the third pixel circuit, and wires electrically connected to the third pixel circuit, and wherein, in a plan view, a center of the hole area may be located within an imaginary triangle defined by connecting a center of the first light-emitting area, a center of the second light-emitting area, and a center of the third light-emitting area.

According to some embodiments, the display panel may further include a blocking metal layer between an upper surface of the substrate and the driving transistor of the first pixel circuit, between the upper surface of the substrate and the driving transistor of the second pixel circuit, and between the upper surface of the substrate and the driving transistor of the third pixel circuit, wherein the blocking metal layer may include a first blocking metal portion including a first main portion overlapping a channel region of the driving transistor of the first pixel circuit and a first branch portion connected to the first main portion and extending in a third direction opposite to the second direction from the first main portion, a second blocking metal portion including a second main portion overlapping a channel region of the driving transistor of the second pixel circuit and a second branch portion connected to the second main portion and extending in the third direction from the second main portion, and a third blocking metal portion including a third main portion overlapping a channel region of the driving transistor of the third pixel circuit and a third branch portion connected to the third main portion and extending in the third direction from the third main portion, wherein a length of the third branch portion along the third direction may be smaller than a length of the first branch portion along the third direction and a length of the second branch portion along the third direction.

According to some embodiments, the display panel may further include a first initialization control line extending in the first direction, wherein, in a plan view, the first initialization control line may intersect the first branch portion and the second branch portion, and may be spaced apart from the third branch portion and the hole area.

According to some embodiments, each of the first pixel circuit, the second pixel circuit, and the third pixel circuit may further include a first initialization transistor including a first initialization semiconductor layer and a first initialization gate electrode, and the first initialization control line may include the first initialization gate electrode of each of the first pixel circuit, the second pixel circuit, and the third pixel circuit.

According to some embodiments, the first initialization semiconductor layer of the first initialization transistor may be on a different layer from a driving semiconductor layer of the driving transistor of each of the first pixel circuit, the second pixel circuit, and the third pixel circuit.

According to some embodiments, the display panel may further include a first initialization voltage line extending in the first direction and electrically connected to the first initialization semiconductor layer of the first initialization transistor of each of the first pixel circuit, the second pixel circuit, and the third pixel circuit.

According to some embodiments, the first initialization voltage line may include a first portion intersecting the first branch portion and the second branch portion, in a plan view, and a second portion adjacent to the hole area, in a plan view, and at least a part of the second portion of the first initialization voltage line may be curved along a perimeter of the hole area, in a plan view.

According to some embodiments, the first portion may extend in a straight line along the first direction in a plan view.

According to some embodiments, the pixel defining layer may include a light-blocking insulating layer.

According to some embodiments, each of the first light-emitting element, the second light-emitting element, and the third light-emitting element may include a pixel electrode, an emission layer on the pixel electrode, and a counter electrode on the emission layer, wherein the counter electrode may be integrally provided corresponding to the first light-emitting element, the second light-emitting element, and the third light-emitting element, and the counter electrode may include an opening corresponding to the hole area.

According to some embodiments of the present disclosure, a display panel includes a first pixel circuit, a second pixel circuit, and a third pixel circuit each including a first transistor and a second transistor on a substrate, and being adjacent along a first direction, a first light-emitting element, a second light-emitting element, and a third light-emitting element, electrically connected to the first pixel circuit, the second pixel circuit, and the third pixel circuit, respectively, and a pixel defining layer including a first pixel opening defining a first light-emitting area of the first light-emitting element, a second pixel opening defining a second light-emitting area of the second light-emitting element, a third pixel opening defining a third light-emitting area of the third light-emitting element, and an opening defining a hole area located between the first light-emitting area, the second light-emitting area, and the third light-emitting area, wherein, in a plan view, the first light-emitting area and the second light-emitting area may be arranged along a second direction perpendicular to the first direction, and the third light-emitting area may be arranged along the first direction from each of the first light-emitting area and the second light-emitting area, and wherein the first light-emitting area, the hole area, and the second light-emitting area may be arranged staggered along the second direction.

According to some embodiments, the display panel may further include a first initialization voltage line extending in the first direction and electrically connected to the second transistor of each of the first pixel circuit, the second pixel circuit, and the third pixel circuit, wherein the first initialization voltage line may include a first portion extending in a straight line along the first direction, in a plan view, and a second portion at least partially curved along the perimeter of the hole area and spaced apart from the hole area, in a plan view.

According to some embodiments, the first transistor may include a first semiconductor layer and a first gate electrode on the first semiconductor layer, the second transistor may include a second semiconductor layer on the first gate electrode and a second gate electrode on the second semiconductor layer, and the first initialization voltage line may be electrically connected to the second semiconductor layer of the second transistor.

According to some embodiments, the display panel may further include a blocking metal layer between an upper surface of the substrate and the first transistor of the first pixel circuit, between the upper surface of the substrate and the first transistor of the second pixel circuit, and between the upper surface of the substrate and the first transistor of the third pixel circuit, wherein, in a plan view, the first portion of the first initialization voltage line may intersect a part of the blocking metal layer, and the second portion of the first initialization voltage line may be spaced apart from the blocking metal layer.

According to some embodiments, the blocking metal layer may include a first blocking metal portion including a first main portion overlapping a channel region of the first transistor of the first pixel circuit and a first branch portion connected to the first main portion and extending in a third direction opposite to the second direction from the first main portion, a second blocking metal portion including a second main portion overlapping a channel region of the first transistor of the second pixel circuit and a second branch portion connected to the second main portion and extending in the third direction from the second main portion, and a third blocking metal portion including a third main portion overlapping a channel region of the first transistor of the third pixel circuit and a third branch portion connected to the third main portion and extending in the third direction from the third main portion, wherein a length of the third branch portion along the third direction may be smaller than a length of the first branch portion along the third direction and a length of the second branch portion along the third direction.

According to some embodiments, the display panel may further include a first initialization control line extending in the first direction, wherein, in a plan view, the first initialization control line may intersect the first branch portion and the second branch portion, and may be spaced apart from the third branch portion and the hole area.

According to some embodiments, the first initialization control line may include a second gate electrode of the second transistor of each of the first pixel circuit, the second pixel circuit, and the third pixel circuit.

According to some embodiments, the pixel defining layer may include a light-blocking insulating layer.

According to some embodiments, each of the first light-emitting element, the second light-emitting element, and the third light-emitting element may include a pixel electrode, an emission layer on the pixel electrode, and a counter electrode on the emission layer, wherein the counter electrode may be integrally provided corresponding to the first light-emitting element, the second light-emitting element, and the third light-emitting element, and includes an opening corresponding to the hole area.

According to some embodiments of the present disclosure, an electronic device includes a display panel, and a component on a lower surface of the display panel, wherein the display panel may include a first pixel circuit, a second pixel circuit, and a third pixel circuit each including a driving transistor and a capacitor on a substrate, and being adjacent along a first direction, a first light-emitting element, a second light-emitting element, and a third light-emitting element, electrically connected to the first pixel circuit, the second pixel circuit, and the third pixel circuit, respectively; and a pixel defining layer including a first pixel opening defining a first light-emitting area of the first light-emitting element, a second pixel opening defining a second light-emitting area of the second light-emitting element, a third pixel opening defining a third light-emitting area of the third light-emitting element, and an opening defining a hole area, wherein, in a plan view, the first light-emitting area and the second light-emitting area may be arranged along a second direction perpendicular to the first direction, and the third light-emitting area is arranged along the first direction from each of the first light-emitting area and the second light-emitting area, wherein, in a plan view, the hole area may be arranged spaced apart from circuit elements constituting the first pixel circuit, wires electrically connected to the first pixel circuit, circuit elements constituting the second pixel circuit, wires electrically connected to the second pixel circuit, circuit elements constituting the third pixel circuit, and wires electrically connected to the third pixel circuit, wherein, in a plan view, a center of the hole area may be located within an imaginary triangle defined by connecting a center of the first light-emitting area, a center of the second light-emitting area, and a center of the third light-emitting area, and wherein the component may overlap the hole area.

### BRIEF DESCRIPTION OF THE DRAWINGS

The above and other aspects, features, and characteristics of certain embodiments of the disclosure will be more apparent from the following description taken in conjunction with the accompanying drawings, in which:

FIGS. 1A and 1B are schematic plan views of an electronic device according to some embodiments, respectively;

FIG. 2 is a schematic cross-sectional view of a portion of a cross-section of the electronic device according to some embodiments;

FIG. 3 is a schematic plan view of a display panel according to some embodiments;

FIG. 4 is an equivalent circuit diagram of a pixel circuit driving a pixel according to some embodiments;

FIG. F 5 is a schematic cross-sectional view of a portion of a display panel in a display area of FIG. 3;

FIG. 6 is a schematic plan view of an arrangement of light-emitting areas and hole areas in a first display area according to some embodiments;

FIG. 7 is a schematic plan view of an arrangement of light-emitting areas in a second display area according to some embodiments;

FIG. 8 is a schematic cross-sectional view of a display panel in a first display area according to some embodiments;

FIG. 9 is a plan view of a first pixel circuit, a second pixel circuit, and a third pixel circuit arranged in a first display area of a display panel according to some embodiments;

FIGS. 10 to 17 are plan views according to a stacking order of components constituting the first to third pixel circuits illustrated in FIG. 9, according to some embodiments; and

FIG. 18 is a plan view of an arrangement of the light-emitting areas of the light-emitting elements of the first pixel circuit, the second pixel circuit, and the third pixel circuit and the hole areas in the first display area of FIG. 9, according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

One or more embodiments may be modified in various ways and may have various embodiments, and thus, specific embodiments are illustrated in the drawings and described in detail in the detailed description. Effects and features of one or more embodiments and methods for achieving the same could become clear by referring to embodiments described in detail below along with the drawings. However, one or more embodiments are not limited to the embodiments described below and may be implemented in various forms.

Hereinafter, aspects of some embodiments will be described in more detail with reference to the accompanying drawings, and in the following description with reference to the drawings, like reference numerals refer to like components and some redundant descriptions thereof may be omitted.

In the following embodiments, the terms “first” and “second” are not used in a limited sense and are used to distinguish one component from another component.

Herein, singular expressions include plural expressions, unless the context clearly dictates otherwise.

In the following embodiments, terms such as “comprise,” “include,” or “have” mean that a feature or component described in the specification is present, and do not exclude the possibility that one or more other features or components may be added.

Herein, when a part of a film, area, element, or the like is located over or on another part, it refers not only to a case where the part is directly on top of the other part, but also a case where another film, area, element, or the like is located therebetween.

In the drawings, for convenience of description, the sizes of elements may be exaggerated or reduced. For example, the size and thickness of each element shown in the drawings are shown arbitrarily for convenience of description, and thus, one or more embodiments are not necessarily limited to shown.

According to embodiments, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

When referring to “in a plan view,” it means viewing the target portion from above (e.g., in a direction perpendicular to an upper surface of the substrate), and when referring to “cross-sectional view,” it means viewing the target portion from the side after a vertical cross-section cut.

When a layer, region, component, or the like is connected to another layer, region, component, or the like, the layer, the region, the component, or the like may be not only directly connected thereto, but also indirectly connected thereto with an intervening layer, region, component, or the like therebetween. For example, it will be understood in this specification that when a layer, an area, or an element is referred to as being in contact with or electrically connected to another layer, area, or element, it may be directly or indirectly in contact with or electrically connected to the other layer, area, or element.

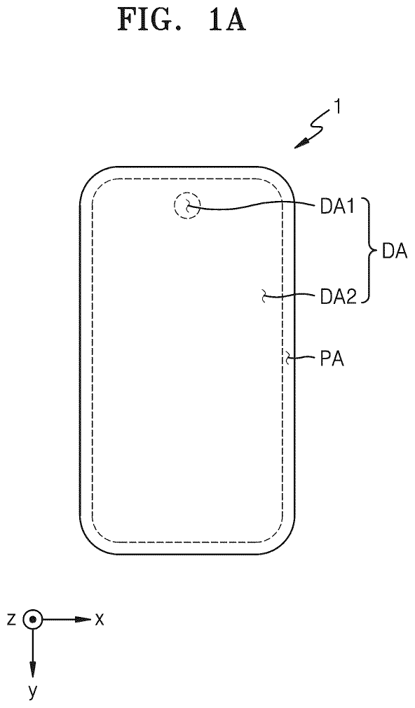

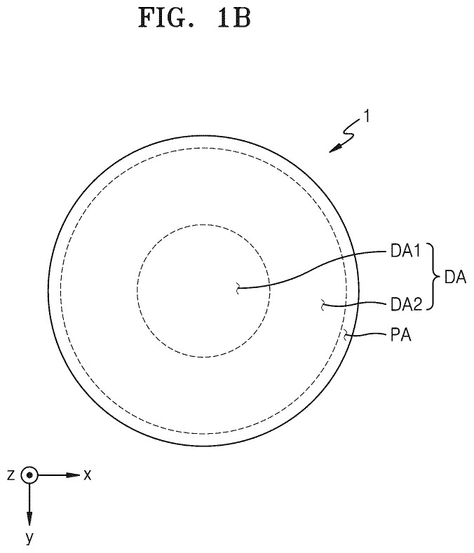

FIGS. 1A and 1B are schematic plan views of an electronic device 1 according to some embodiments, respectively.

According to some embodiments, the electronic device 1 displays video images (e.g., moving images) or still images (e.g., static images) and may be used not only as a portable electronic device such as a mobile phone, a smart phone, a tablet personal computer PC, a mobile communication terminal, an electronic organizer, an electronic book, a portable multimedia player (PMP), a navigation device, and an ultra-mobile personal computer (UMPC), but also as a display screen of various products such as televisions, laptops, monitors, billboards, and Internet of Things (IoT) devices. According to some embodiments, the electronic device 1 may be used in wearable devices such as smart watches, watch phones, glasses-type displays, or head mounted displays (HMDs). According to some embodiments, the electronic device 1 may be used as a dashboard in a vehicle, a center information display (CID) of a center fascia or dashboard in a vehicle, a room mirror display that replaces the side mirrors of a vehicle, and a display screen arranged on the rear side of a front seat to serve as an entertainment device for back seat passengers of vehicles.

For convenience of explanation, FIGS. 1A and 1B illustrate aspects of the electronic device 1 used as a smart phone and a smart watch, respectively, according to some embodiments.

Referring to FIGS. 1A and 1B, the electronic device 1 may include a display area DA and a peripheral area PA outside (e.g., surrounding, in a periphery, or outside a footprint of) the display area DA.

According to some embodiments as shown in FIG. 1A, the display area DA may have a rectangular shape in a plan view (e.g., a view from a direction normal or perpendicular to a display surface of the display area DA). According to some embodiments as shown in FIG. 1B, the display area DA may have a circular shape in a plan view. According to some embodiments, the display area DA may have, in a plan view, a polygonal shape such as a triangle, a pentagon, or a hexagon, an oval shape, or an atypical or irregular shape, etc. According to some embodiments, a corner of an edge of the display area DA may be round.

Pixels including various display elements, such as an organic light-emitting element, may be arranged in the display area DA. The peripheral area PA may be a non-display area where display elements are not arranged. The display area DA may be entirely surrounded by the peripheral area PA.

The display area DA may include a first display area DA1 and a second display area DA2. At least a portion of the display area DA may be set as the first display area DA1. As illustrated in FIG. 1A and FIG. 1B, a portion of the display area DA may be the first display area DA1, and a remaining portion may be the second display area DA2. According to some embodiments, the entire display area DA may be the first display area DA1.

The second display area DA2 may have a shape surrounding the first display area DA1, as illustrated in FIGS. 1A and 1B. However, embodiments according to the present disclosure are not limited thereto and may be modified in various ways, such as the second display area DA2 partially surrounding the first display area DA1.

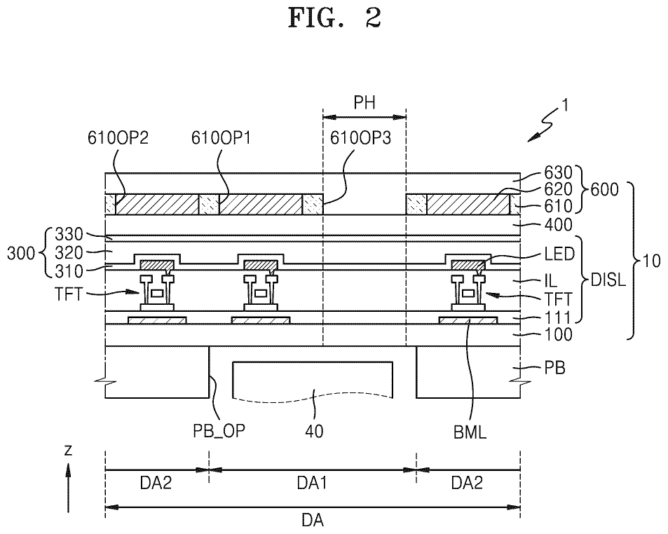

As described below with reference to FIG. 2, the first display area DA1 may be an area where a component 40 is located below the display panel 10. For example, the first display area DA1 may be referred to as a component area. For example, the component 40 may be a camera, an illumination sensor, a proximity sensor, or an iris sensor, etc. According to some embodiments, the first display area DA1 may be an area having a higher transmittance than the second display area DA2.

The shape, area, and arrangement of the first display area DA1 may vary depending on the embodiments. For example, in a plan view, the first display area DA1 may have various shapes, such as a circle, an oval, a polygon (e.g., a square), a star shape, or a diamond shape.

FIGS. 1A and 1B illustrate that one first display area DA1 is located within the second display area DA2, but embodiments according to the present disclosure are not limited thereto. According to some embodiments, the electronic device 1 may have two or more first display areas DA1, and the shapes and sizes of a plurality of first display areas DA1 may be different from each other. Components 40 with different functions may be arranged respectively corresponding to the plurality of first display areas DA1. According to some embodiments, when the electronic device 1 has a plurality of first display areas DA1, a camera may be placed in one first display area DA1, an illumination sensor may be placed in another first display area DA1, and a proximity sensor may be placed in still another first display area DA1.

FIG. 2 is a schematic cross-sectional view of a portion of a cross-section of the electronic device 1 according to some embodiments.

Referring to FIG. 2, the electronic device 1 may include a display panel 10 and the component 40. The electronic device 1 may further include a window protecting the display panel 10 on the display panel 10.

The display panel 10 may include the display area DA. The display area DA may include the first display area DA1 and a second display area DA2.

The display panel 10 may include a substrate 100, a display layer DISL, a touch-screen layer 400, an anti-reflection layer 600, and a lower protective film PB.

The substrate 100 may include glass or a polymer resin. The substrate 100 including the polymer resin may be flexible, foldable, rollable, or bendable. The substrate 100 may have a multi-layer structure including a layer including the polymer resin and an inorganic layer.

The display layer DISL may include a pixel circuit including a thin film transistor TFT, a light-emitting element LED that is a display element, and an encapsulation layer 300. The light-emitting element LED may be electrically connected to the thin film transistor TFT. FIG. 2 illustrates that a buffer layer 111 is located on the substrate 100 and the thin film transistor TFT is located on the buffer layer 111. The thin-film transistor TFT and the light-emitting element LED electrically connected to the thin-film transistor TFT may be respectively arranged in the first display area DA1 and the second display area DA2.

The first display area DA1 may include a plurality of hole areas PH where the display element, circuit elements constituting the pixel circuit and wires electrically connected to the pixel circuit are not arranged. The hole area PH may be an area through which light/signal emitted from the component 40 located below the substrate 100 in the first display area DA1 or light/signal incident on the component 40 is transmitted. For example, the hole area PH may be referred to as a transmission region.

A blocking metal layer BML may be located in the first display area DA1. The blocking metal layer BML may be located between the substrate 100 and the buffer layer 111 to prevent or reduce instances of the function of the thin film transistor TFT located in the first display area DA1 being deteriorated by light passing through the first display area DA1. The blocking metal layer BML located in the first display area DA1 may include an opening overlapping the hole area PH. According to some embodiments, the blocking metal layer BML may also be located in the second display area DA2.

The encapsulation layer 300 may include at least one inorganic encapsulation layer and at least one organic encapsulation layer. According to some embodiments, the encapsulation layer 300 may include a first inorganic encapsulation layer 310, a second inorganic encapsulation layer 330, and an organic encapsulation layer 320 between the first inorganic encapsulation layer 310 and the second inorganic encapsulation layer 330.

The touch-screen layer 400 may be located on the encapsulation layer 300. The touch-screen layer 400 may obtain coordinate information according to an external input, for example, a touch event of an object, such as a user's finger or a stylus pen. The touch-screen layer 400 may include a touch electrode and wires connected to the touch electrode. The touch-screen layer 400 may detect the external input via a magnetic capacitance method or a mutual capacitance method.

The anti-reflection layer 600 may reduce the reflectance of light (external light) incident from the outside towards the electronic device 1. The anti-reflection layer 600 may include a light-shielding layer 610 and color filters 620. The anti-reflection layer 600 may further include an overcoated layer 630 located on the light-shielding layer 610 and the color filters 620.

The light-shielding layer 610 may include a first opening 610OP1 overlapping the light-emitting element LED in the first display area DA1, and a second opening 610OP2 overlapping the light-emitting element LED in the second display area DA2. The light-shielding layer 610 may include a third opening 610OP3 not overlapping the light-emitting element LED. The third opening 610OP3 of the light-shielding layer 610 may correspond to the hole area PH. The third opening 610OP3 of the light-shielding layer 610 may be located in the first display area DA1. A portion of the overcoated layer 630 may be located in the third opening 610OP3 of the light-shielding layer 610. The color filters 620 and the light-shielding layer 610 may not be located in the hole area PH.

The color filters 620 may be respectively located within the first opening 610OP1 and the second opening 610OP2 of the light-shielding layer 610. The color filters 620 may have a color corresponding to light emitted from the light-emitting element LED. For example, the color filters 620 may have red, green, or blue.

The overcoated layer 630 is a colorless transmissive layer without a color of a visible light wavelength band, and may flatten an upper surface of the light-shielding layer 610 and an upper surface of the color filters 620. The overcoated layer 630 may include a colorless transmissive organic material, such as an acryl-based resin.

A window may be located on an upper portion of the display panel 10, for example, on the anti-reflection layer 600, to protect the display panel 10. The window may be combined with the anti-reflection layer 600 via an adhesive layer, such as an optically clear adhesive. The window may include a glass material or a plastic material. The glass material may include ultra-thin glass. The plastic material may include polyether sulfone, polyacrylate, polyether imide, polyethylene naphthalate, polyethylene terephthalate, polyphenylene sulfide, polyarylate, polyimide, polycarbonate, or cellulose acetate propionate.

The lower protective film PB may be attached to a lower surface of the substrate 100 to support and protect the substrate 100. The lower protective film PB may have an opening PB_OP corresponding to the first display area DA1. The lower protective film PB includes the opening PB_OP, thereby enhancing the transmittance of the first display area DA1. According to some embodiments, an area of the opening PB_OP of the lower protective film PB may be greater than an area in which the component 40 is located. The lower protective film PB may include polyethylene terephthalate (PET) or polyimide (PI).

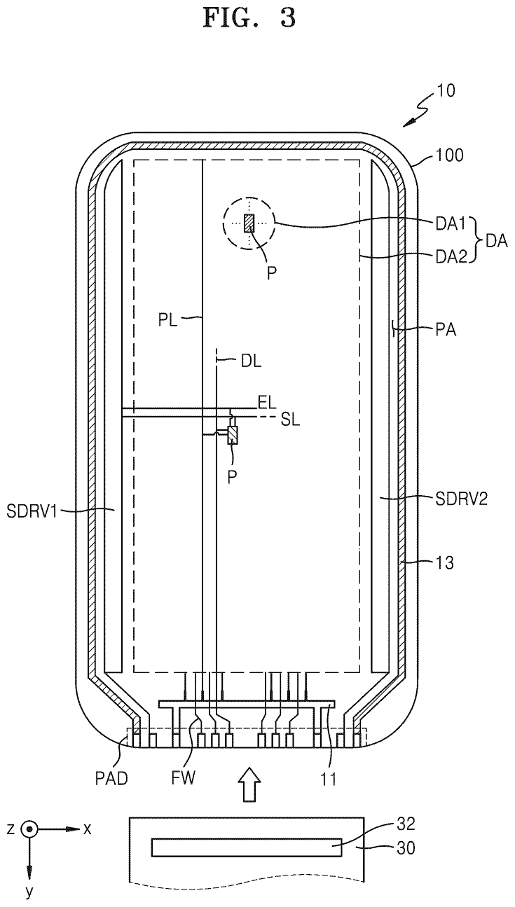

FIG. 3 is a schematic plan view of the display panel 10 according to some embodiments.

Referring to FIG. 3, the display panel 10 includes a substrate 100, and the display panel 10 includes the display area DA and the peripheral area PA located outside the display area DA, so it may also be said that the substrate 100 includes the display area DA and the peripheral area PA.

A plurality of pixels P may be arranged in the display area DA. A plurality of pixels P may be arranged in the first display area DA1 and the second display area DA2. Each of the pixels P may include a display element such as an organic light-emitting element and a pixel circuit electrically connected to the display element. Each of the pixels P may emit, for example, red, green, or white light.

Each of the pixel circuits of the pixels P may be electrically connected to peripheral circuits arranged in the peripheral area PA. A first scan driving circuit SDRV1, a second scan driving circuit SDRV2, a terminal portion PAD, a driving voltage supply line 11, and a common voltage supply line 13 may be arranged in the peripheral area PA.

The first scan driving circuit SDRV1 may apply a scan signal to each of the pixel circuits via a first scan line SL. The first scan driving circuit SDRV1 may apply an emission control signal to each pixel circuit via an emission control line EL. The second scan driving circuit SDRV2 may be located on an opposite side of the first scan driving circuit SDRV1, based on the display area DA, and may be parallel (or approximately parallel) to the first scan driving circuit SDRV1. Some of pixel circuits of the pixels P in the display area DA may be electrically connected to the first scan driving circuit SDRV1 and the remaining pixel circuits may be electrically connected to the second scan driving circuit SDRV2. The second scan driving circuit SDRV2 may be omitted.

The terminal portion PAD may be arranged at one side of the substrate 100. The terminal portion PAD may not be covered by an insulating layer and be exposed to be connected to a display circuit board 30. A display driving unit 32 may be arranged in the display circuit board 30.

The display driving unit 32 may be configured to generate a control signal transmitted to the first scan driving circuit SDRV1 and the second scan driving circuit SDRV2. The display driving unit 32 may be configured to generate a data signal, and the generated data signal may be transmitted to the pixel circuits of the pixels P via a fan-out line FW and a data line DL connected to the fan-out line FW.

The display driving unit 32 may be configured to supply a driving voltage ELVDD to the driving voltage supply line 11 and supply a common voltage ELVSS to the common voltage supply line 13. The driving voltage ELVDD may be applied to pixel circuits of the pixels P via a driving voltage line PL connected to the driving voltage supply line 11, and the common voltage ELVSS may be applied to a counter electrode of the display element via the common voltage supply line 13.

The driving voltage supply line 11 may be connected to the terminal portion PAD and may extend below the display area DA in a first direction (e.g., x direction). The common voltage supply line 13 may be connected to the terminal portion PAD and may partially surround the display area DA by having a loop shape in which one side is open.

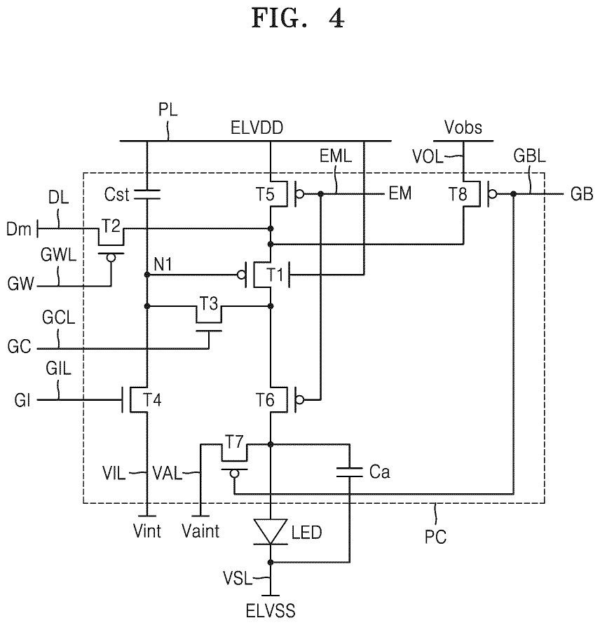

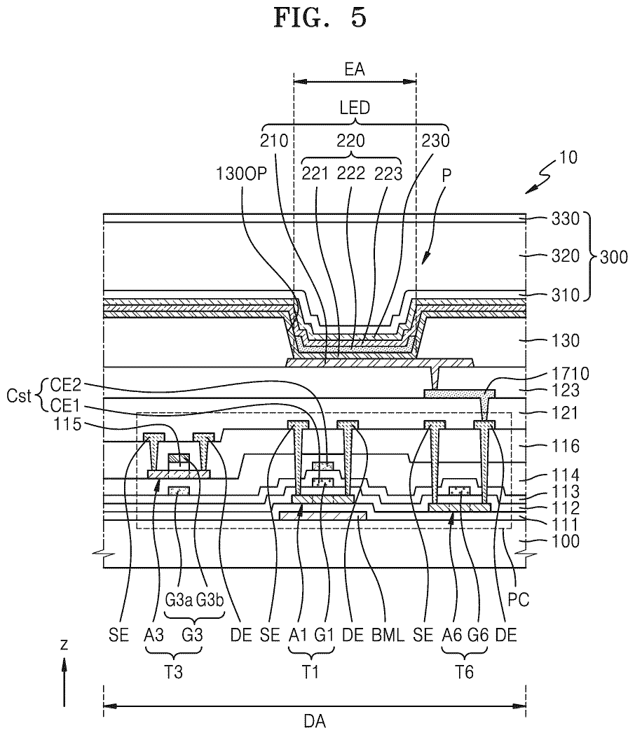

FIG. 4 is an equivalent circuit diagram of a pixel circuit PC driving a pixel P according to some embodiments. Although FIG. 4 illustrates various components in a pixel circuit according to some embodiments, embodiments according to the present disclosure are not limited thereto, and according to various embodiments, the pixel circuit may include additional components or fewer components without departing from the spirit and scope of embodiments according to the present disclosure.

Referring to FIG. 4, the pixel circuit PC may be connected to each of gate lines, for example, a scan line GWL, a first initialization control line GIL, a second initialization control line GBL, a compensation scan line GCL, and an emission control line EML, and receive a scan signal GW, a first initialization control signal GI, a second initialization control signal GB, a compensation scan signal GC, and an emission control signal EM. For example, the scan line GWL, the first initialization control line GIL, the second initialization control line GBL, the compensation scan line GCL, and the emission control line EML of FIG. 4 may be gate lines connected to the pixel circuit PC located in an (i)th row, wherein i is a natural number.

The pixel circuit PC may be configured to receive the data signal Dm through the data line DL. For example, the data line DL of FIG. 4 may be a signal line connected to the pixel circuit PC located in a (j)th column, wherein j is a natural number.

The pixel circuit PC according to some embodiments may be electrically connected to the light-emitting element LED emitting light of a certain color, and the light-emitting element LED may include the first electrode (pixel electrode or anode), the second electrode (counter electrode or cathode), and an intermediate layer therebetween.

The pixel circuit PC may include a plurality of transistors T1, T2, T3, T4, T5, T6, T7, and T8, and capacitors Cst and Ca. The plurality of transistors T1, T2, T3, T4, T5, T6, T7, and T8 may include a driving transistor T1, a data write transistor T2, a compensation transistor T3, a first initialization transistor T4, an operation control transistor T5, an emission control transistor T6, a second initialization transistor T7, and a bias transistor T8. The capacitors Cst and Ca may include a first capacitor Cst and a second capacitor Ca.

According to some embodiments, some of the plurality of transistors T1, T2, T3, T4, T5, T6, T7, and T8 may be p-channel metal oxide semiconductor field-effect transistors (p-channel MOSFETs) (PMOS) and the remaining ones may be n-channel metal oxide semiconductor field-effect transistors (n-channel MOSFETs) (NMOS). For example, among the plurality of transistors T1, T2, T3, T4, T5, T6, T7, and T8, the driving transistor T1, the data write transistor T2, the operation control transistor T5, the emission control transistor T6, the second initialization transistor T7, and the bias transistor T8 may be PMOS, and the compensation transistor T3 and the first initialization transistor T4 may be NMOS. Alternatively, among the plurality of transistors T1, T2, T3, T4, T5, T6, T7, and T8, the compensation transistor T3 and the first initialization transistor T4 may be PMOS and the remaining ones may be NMOS. Alternatively, all of the plurality of transistors T1, T2, T3, T4, T5, T6, T7, and T8 may be NMOS or PMOS. Hereinafter, embodiments in which the compensation transistor T3 and first initialization transistor T4 are NMOS including an oxide semiconductor, and the remaining ones are PMOS will be mainly described.

According to some embodiments, at least one of the plurality of transistors T1, T2, T3, T4, T5, T6, T7, or T8 may be a transistor including a low-temperature polycrystalline silicon (LTPS) semiconductor layer, and at least one of the plurality of transistors T1, T2, T3, T4, T5, T6, T7, or T8 may be a transistor including an oxide semiconductor layer.

The driving transistor T1 that directly affects brightness of the display panel 10 may include a semiconductor layer including polycrystalline silicon having high reliability so that the display panel 10 may have high resolution. Because an oxide semiconductor has high carrier mobility and a low leakage current, a voltage drop is not large even when a driving time is long. In other words, a color change of an image caused by the voltage drop is not large even during low-frequency driving, and thus, the low-frequency driving is possible. As such, because the oxide semiconductor has a low leakage current, at least one of the compensation transistor T3 or the first initialization transistor T4 connected to a driving gate electrode of the driving transistor T1 may include the oxide semiconductor so as to prevent or reduce a leakage current that may flow to the driving gate electrode while reducing power consumption. For example, the driving transistor T1, the data write transistor T2, the operation control transistor T5, the emission control transistor T6, the second initialization transistor T7, and the bias transistor T8 may be transistors including an LTPS semiconductor layer, and the compensation transistor T3 and the first initialization transistor T4 may be transistors including an oxide semiconductor layer.

The driving transistor T1 may be connected between the light-emitting element LED and the driving voltage line PL configured to provide the driving voltage ELVDD. The driving transistor T1 includes one gate electrode and another gate electrode, which are connected to node N1 and the driving voltage line PL, respectively. The two gate electrodes may be disposed to face each other at (e.g., in or on) different layers from each other. For example, the gate electrodes of the driving transistor T1 may face each other with a semiconductor layer interposed therebetween. The one gate electrode of the driving transistor T1 may be connected to one end of the first capacitor Cst that is a storage capacitor. The one gate electrode of the driving transistor T1 may be connected to a first node N1. A source electrode of the driving transistor T1 may be connected to the driving voltage line PL via the operation control transistor T5. A drain electrode of the driving transistor T1 may be electrically connected to the first electrode (or the pixel electrode or the anode) of the light-emitting element LED via the emission control transistor T6. The driving transistor T1 may be configured to receive the data signal Dm transmitted from the data line DL and supply a driving current to the light-emitting element LED, according to a switching operation of the data write transistor T2.

A gate electrode of the data write transistor T2 may be connected to the scan line GWL. A first electrode of the data write transistor T2 may be connected to the data line DL and a second electrode thereof may be connected to the source electrode of the driving transistor T1. The data write transistor T2 may be turned on according to the scan signal GW received through the scan line GWL and transmit the data signal Dm received through the data line DL to the source electrode of the driving transistor T1, and the data signal Dm may be transmitted to the gate electrode of the driving transistor T1 by the compensation transistor T3 that is simultaneously (or concurrently) turned on.

A gate electrode of the compensation transistor T3 may be connected to the compensation scan line GCL. A first electrode of the compensation transistor T3 may be connected to the drain electrode of the driving transistor T1 and a second electrode thereof may be connected to the first node N1. The compensation transistor T3 may be turned on according to the compensation scan signal GC received through the compensation scan line GCL and compensate for a threshold voltage (Vth) of the driving transistor T1 by connecting the gate electrode to the drain electrode of the driving transistor T1 for diode-connection of the driving transistor T1.

A gate electrode of the first initialization transistor T4 may be connected to the first initialization control line GIL. A first electrode of the first initialization transistor T4 may be connected to a first initialization voltage line VIL and a second electrode thereof may be connected to the first node N1. The first initialization transistor T4 may be turned on according to the first initialization control signal GI applied from the first initialization control line GIL and initialize a potential of the gate electrode of the driving transistor T1 (i.e., a potential of the first node N1) to a specific voltage by transmitting the first initialization voltage Vint to the gate electrode of the driving transistor T1. The first initialization voltage Vint may have a voltage level higher than or same as the common voltage ELVSS.

A gate electrode of the operation control transistor T5 may be connected to the emission control line EML. A first electrode of the operation control transistor T5 may be connected to the driving voltage line PL and a second electrode thereof may be connected to the source electrode of the driving transistor T1.

A gate electrode of the emission control transistor T6 may be connected to the emission control line EML. A first electrode of the emission control transistor T6 may be connected to the drain electrode of the driving transistor T1, and a second electrode thereof may be electrically connected to the first electrode (or the pixel electrode or the anode) of the light-emitting element LED. The operation control transistor T5 and the emission control transistor T6 may be simultaneously (or concurrently) turned on according to the emission control signal EM applied from the emission control line EML. The driving voltage ELVDD applied through the turned-on operation control transistor T5 may be transmitted to the light-emitting element LED after being compensated for through the driving transistor T1.

A gate electrode of the second initialization transistor T7 may be connected to the second initialization control line GBL. A first electrode of the second initialization transistor T7 may be connected to the first electrode (or the pixel electrode or the anode) of the light-emitting element LED, and a second electrode thereof may be connected to a second initialization voltage line VAL. The second initialization transistor T7 may be turned on by the second initialization control signal GB applied from the second initialization control line GBL and initialize the first electrode (or the pixel electrode or the anode) of the light-emitting element LED. The second initialization control signal GB may be a same signal as or a different signal from the first initialization control signal GI.

According to a comparative example of the disclosure, when the light-emitting element LED emits light even when a minimum current of the driving transistor T1 displaying a black image flows as the driving current, the black image may not be properly displayed. However, according to some embodiments of the disclosure, the second initialization transistor T7 may be configured to distribute, as a bypass current, a part of the minimum current of the driving transistor T1 to a current path other than a current path towards the light-emitting element LED. Here, the minimum current of the driving transistor T1 may denote a current under a condition where the driving transistor T1 is turned off because a gate-source voltage (Vgs) of the driving transistor T1 is smaller than the threshold voltage (Vth). As such, a minimum driving current (e.g., a current of 10 picoampere (pA) or lower) under a condition where the driving transistor T1 is turned off is transmitted to the light-emitting element LED, and thus, an image of black luminance may be displayed. When the minimum driving current for displaying the black image flows, an effect of bypass transmission of the bypass current is large, but when a large driving current for displaying an image such as a general image or white image flows, an effect of the bypass current may be negligible (or almost negligible). Accordingly, when a driving current for displaying a black image flows, a contrast ratio may be relatively improved by realizing an accurate black luminance image by using the second initialization transistor T7 from the driving current. Thus, the display panel 10 with relatively improved display quality may be provided.

A gate electrode of the bias transistor T8 may be connected to the second initialization control line GBL. A first electrode of the bias transistor T8 may be connected to a bias voltage line VOL configured to provide the bias voltage Vobs, and a second electrode of the bias transistor T8 may be connected to the source electrode of the driving transistor T1.

One end of the first capacitor Cst may be connected to the gate electrode of the driving transistor T1 and the other end thereof may be connected to the driving voltage line PL. The first capacitor Cst may be connected between the driving voltage line PL and the first node N1. The first capacitor Cst may store a voltage between the driving voltage ELVDD and the first node N1.

The second capacitor Ca may be an auxiliary capacitor and electrically connected to the emission control transistor T6, the second initialization transistor T7, the first electrode (or the pixel electrode or the anode) of the light-emitting element LED, and and a common voltage line VSL supplied with the common voltage ELVSS. The second capacitor Ca stores and maintains a voltage corresponding to a voltage difference between the first electrode (or the pixel electrode or the anode) of the light-emitting element LED and the common voltage line VSL while the second initialization transistor T7 is turned on, thereby preventing or reducing an increase in black luminance when the emission control transistor T6 is turned off.

The first electrode (or the pixel electrode or the anode) of the light-emitting element LED may receive the driving current from the driving transistor T1 and emit light to display an image. The driving voltage ELVDD may be a certain high-level voltage and the common voltage ELVSS may be a voltage lower than the driving voltage ELVDD.

Hereinafter, operations of the pixel circuit PC and light-emitting element LED will be described.

During an initialization period, the first initialization control signal GI of a high level may be supplied to the first initialization transistor T4 through the first initialization control line GIL, and the second initialization control signal GB of a low level may be supplied to the second initialization transistor T7 through the second initialization control line GBL. As a result, the first initialization transistor T4 and the second initialization transistor T7 may be turned on. The first initialization voltage Vint applied from the first initialization voltage line VIL may be transmitted to the gate electrode of the driving transistor T1 through the first initialization transistor T4 and transmitted to the anode through the second initialization transistor T7. Accordingly, voltages of the anode and the gate electrode of the driving transistor T1 may be initialized.

Then, during a data write period, the scan signal GW of a low level may be supplied through the scan line GWL, the compensation scan signal GC of a high level may be supplied through the compensation scan line GCL, and the data write transistor T2 and the compensation transistor T3 may be turned on. The data write transistor T2 may be configured to transmit the data signal Dm from the data line DL to the source electrode of the driving transistor T1, and the driving transistor T1 may be diode-connected by the compensation transistor T3. Accordingly, a compensation voltage obtained by subtracting a threshold voltage of the driving transistor T1 from the data signal Dm may be applied to the gate electrode of the driving transistor T1.

The driving voltage ELVDD and the compensation voltage may be applied to both ends of the first capacitor Cst, and charges corresponding to a difference between voltages at the both ends may be stored in the first capacitor Cst.

Then, during an emission period, the emission control signal EM supplied from the emission control line EML may be changed from a high level to a low level, and the operation control transistor T5 and the emission control transistor T6 may be turned on. Consequently, a driving current corresponding to a voltage difference between a voltage of the gate electrode of the driving transistor T1 and the driving voltage ELVDD may be generated, and the driving current may be supplied to the light-emitting element LED through the emission control transistor T6, and thus, the light-emitting element LED may emit light.

Characteristics of the light-emitting elements LED emitting light of different colors and/or characteristics of the driving transistors T1 of the pixel circuits PC may be different. In particular, color coordinates of the display panel 10 may be changed (e.g., reddish) during a high-frequency operation. However, according to the disclosure, a voltage of the source electrode of the driving transistor T1 may be controlled through the bias voltage Vobs by using the bias transistor T8. As such, by controlling a driving current, a pixel-wise luminance deviation (current deviation) and changes in the color coordinates may be relatively improved. Therefore, the display panel 10 may have relatively improved display quality.

FIG. 5 is a schematic cross-sectional view of a portion of the display panel 10 in the display area DA of FIG. 3.

Referring to FIG. 5, a pixel P is illustrated located on the substrate 100. The pixel circuit PC may be located on the substrate 100, and the light-emitting element LED electrically connected to the pixel circuit PC may be located on the substrate 100.

The pixel circuit PC may include a plurality of transistors and capacitors. FIG. 5 illustrates the driving transistor T1, the compensation transistor T3, the emission control transistor T6, and the first capacitor Cst as an example.

According to some embodiments, the blocking metal layer BML may be located on the substrate 100. According to some embodiments, the blocking metal layer BML may be located between an upper surface of the substrate 100 and the driving transistor T1. The blocking metal layer BML may include one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

According to some embodiments, the blocking metal layer BML may be a Mo single layer, may have a double layer structure in which a Mo layer and a Ti layer are stacked, or may have a triple layer structure in which a Ti layer, an Al layer, and a Ti layer are stacked.

When viewed in a direction perpendicular to the upper surface of the substrate 100, the blocking metal layer BML may overlap at least a portion of a driving semiconductor layer A1 of the driving transistor T1. According to some embodiments, the blocking metal layer BML may have a voltage level of constant voltage. According to some embodiments, the blocking metal layer BML prevents or reduces negative (−) charges from gathering below the driving semiconductor layer A1 of the driving transistor T1, thereby preventing or reducing occurrence of an afterimage caused by negative (−) charges.

The buffer layer 111 may be located on the blocking metal layer BML. The buffer layer 111 may be an inorganic insulating layer including an inorganic insulating material, such as a silicon nitride and/or a silicon oxide, and may have a single layer or multilayer structure including the above material.

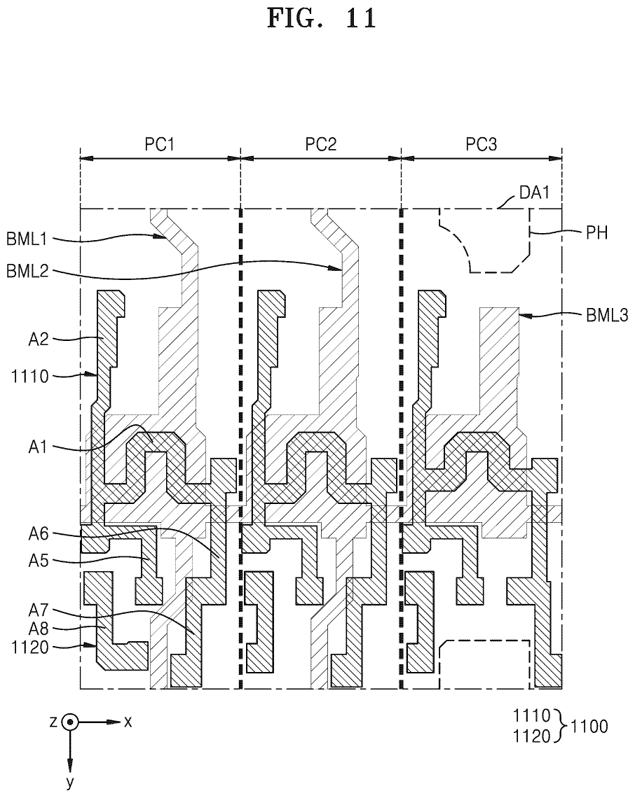

A first semiconductor layer 1100 (see FIG. 11) described below may be located on the buffer layer 111. Transistors may be located on the buffer layer 111. As an example, FIG. 5 illustrates the driving transistor T1 and the emission control transistor T6 located on the buffer layer 111. For example, a semiconductor layer (hereinafter, referred to as a driving semiconductor layer A1) of the driving transistor T1 and a semiconductor layer (hereinafter, referred to as an emission control semiconductor layer A6) of the emission control transistor T6 each corresponding to a portion of a first semiconductor pattern 1110 (see FIG. 11) of a first semiconductor layer 1100 (see FIG. 11) may be located on the buffer layer 111. Each of the driving semiconductor layer A1 and the emission control semiconductor layer A6 may include a channel region, as well as impurity regions located on both sides of the channel region that are doped with impurities.

A first gate insulating layer 112 may be located on the first semiconductor layer 1100 (see FIG. 11). For example, the first gate insulating layer 112 is located on the driving semiconductor layer A1, and the emission control semiconductor layer A6. The first gate insulating layer 112 may be an inorganic insulating layer including an inorganic insulating material, such as silicon oxide, silicon nitride, or silicon oxynitride, and may include a single layer or multilayer structure including the above material.

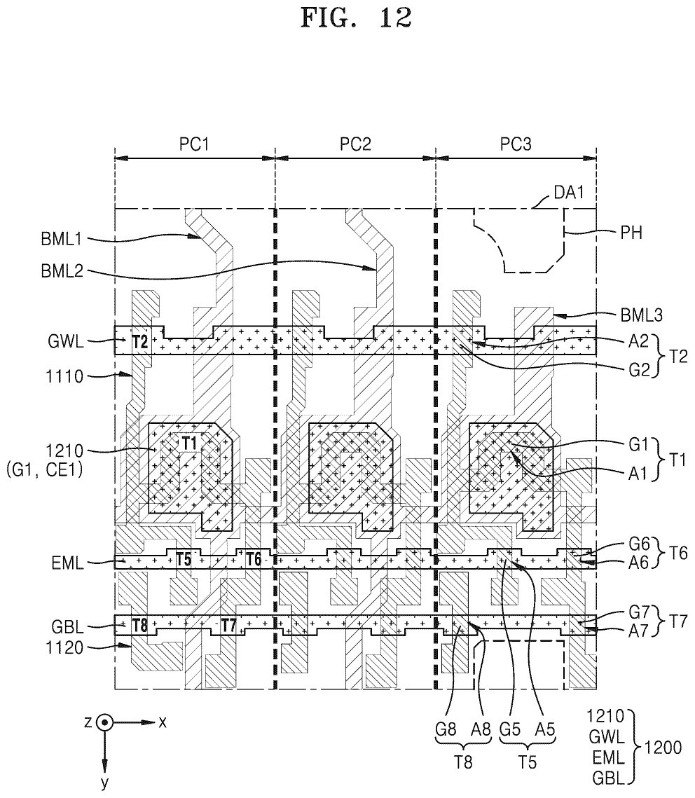

The first conductive layer 1200 (see FIG. 12) described below may be located on the first gate insulating layer 112. For example, a driving gate electrode G1 of the driving transistor T1 and an emission control gate electrode G6 of the emission control transistor T6 may be located on the first gate insulating layer 112. The driving gate electrode G1 of the driving transistor T1 may perform the function of a lower electrode CE1 of the first capacitor Cst. In other words, the driving gate electrode G1 may be integrated with the lower electrode CE1.

The first conductive layer 1200 (see FIG. 12), for example, the driving gate electrode G1 and/or the emission control gate electrode G6, may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed in a single layer or multilayer including the aforementioned material.

A second gate insulating layer 113 may be located on the first conductive layer 1200 (see FIG. 12). For example, the second gate insulating layer 113 may be located on the driving gate electrode G1 and the emission control gate electrode G6. The second gate insulating layer 113 may be an inorganic insulating layer including an inorganic insulating material, such as silicon oxide, silicon nitride, or silicon oxynitride, and may include a single layer or multilayer structure including the above material.

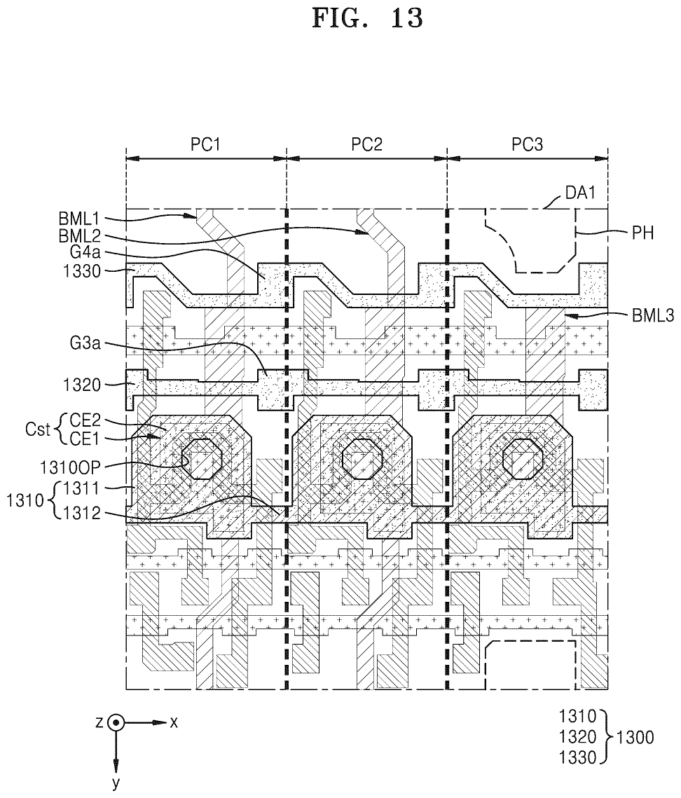

A second conductive layer 1300 (see FIG. 13) described below may be located on the second gate insulating layer 113. For example, an upper electrode CE2 of the first capacitor Cst may be located on the second gate insulating layer 113. The second conductive layer 1300 (see FIG. 13) (e.g., the upper electrode CE2 of the first capacitor Cst) may include may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed in a single layer or multilayer including the aforementioned material. According to some embodiments, the upper electrode CE2 may include a same material as the lower electrode CE1 and/or the blocking metal layer BML.

The upper electrode CE2 may overlap the driving gate electrode G1 and/or the lower electrode CE1.

A first interlayer insulating layer 114 may be located on the second conductive layer 1300 (see FIG. 13) (e.g., the upper electrode CE2 of the first capacitor Cst. The first interlayer insulating layer 114 may be an inorganic insulating layer including an inorganic insulating material, such as silicon oxide, silicon nitride, or silicon oxynitride, and may include a single layer or multilayer structure including the above material.

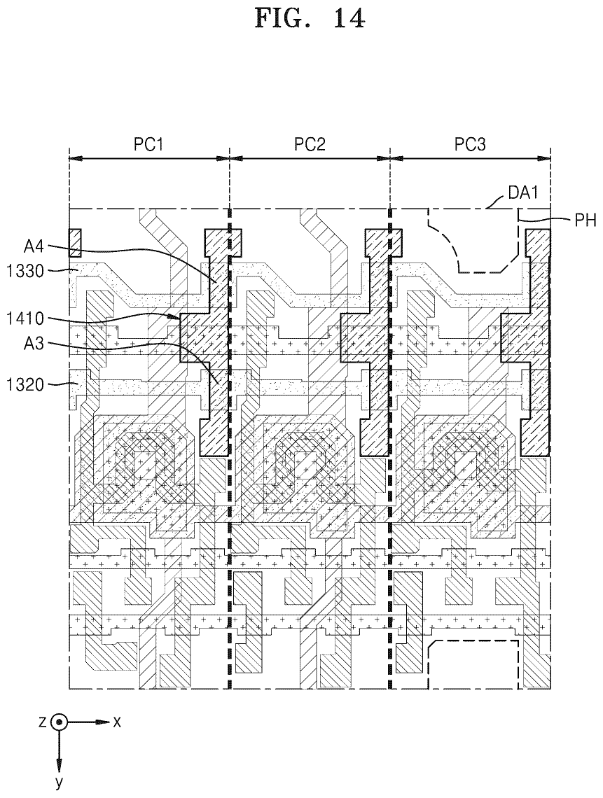

A second semiconductor layer may be located on the first interlayer insulating layer 114. According to some embodiments, a third semiconductor pattern 1410 (see FIG. 14) of the second semiconductor layer may be located on the first interlayer insulating layer 114. For example, a semiconductor layer (hereinafter, referred to as a compensation semiconductor layer A3) of the compensation transistor T3 corresponding to a portion of a third semiconductor pattern 1410 (see FIG. 14) may be located on the first interlayer insulating layer 114.

The compensation semiconductor layer A3 may include a channel region and conductive regions located on both sides of the channel region. The compensation semiconductor layer A3 and the driving semiconductor layer A1 may be arranged on different layers. For example, the driving semiconductor layer A1 may be located on the buffer layer 111 and the compensation semiconductor layer A3 may be located on the first interlayer insulating layer 114. In other words, a vertical distance from the substrate 100 to the compensation semiconductor layer A3 may be greater than a vertical distance from the substrate 100 to the driving semiconductor layer A1.

A third gate electrode G3 may be located below and/or on the compensation semiconductor layer A3. According to some embodiments, FIG. 5 illustrates the third gate electrode G3 including a lower compensation gate electrode G3a located below the compensation semiconductor layer A3 and an upper compensation gate electrode G3b located on the compensation semiconductor layer A3. According to some embodiments, one of the lower compensation gate electrode G3a and the upper compensation gate electrode G3b may be omitted.

The lower compensation gate electrode G3a may include a same material as the upper electrode CE2 and located on a same layer as the upper electrode CE2 (for example, the second gate insulating layer 113). The upper compensation gate electrode G3b may be arranged on the compensation semiconductor layer A3 with a third gate insulating layer 115 therebetween. The upper compensation gate electrode G3b may include Al, Pt, Pd, Ag, Mg, Au, Ni, Nd, Ir, Cr, Li, Ca, Mo, Ti, W, and/or Cu, and may be formed in a single layer or multilayer including the above material.

FIG. 5 illustrates that the third gate insulating layer 115 is located only between the upper compensation gate electrode G3b and the compensation semiconductor layer A3, but the disclosure is not limited thereto. According to some embodiments, the third gate insulating layer 115 may be formed to entirely cover the substrate 100 like another insulating layer, such as the first gate insulating layer 112. The third gate insulating layer 115 may be an inorganic insulating layer including an inorganic insulating material, such as silicon oxide, silicon nitride, or silicon oxynitride, and may include a single layer or multilayer structure including the above material.

A second interlayer insulating layer 116 may be located on the upper compensation gate electrode G3b. The second interlayer insulating layer 116 may be an inorganic insulating layer including an inorganic insulating material, such as silicon oxide, silicon nitride, or silicon oxynitride, and may include a single layer or multilayer structure including the above material.

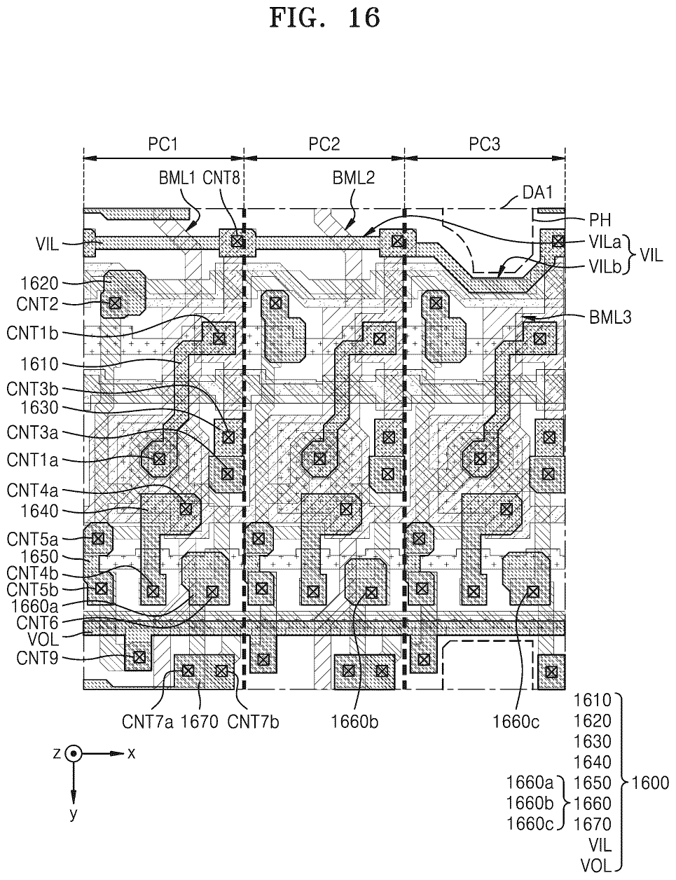

A fourth conductive layer 1600 (see FIG. 16) may be located on the second interlayer insulating layer 116. According to some embodiments, each of a source electrode SE and a drain electrode DE electrically connected to the semiconductor layer of each transistor may be located on the second interlayer insulating layer 116. According to some embodiments, a fifth connection electrode 1650 (see FIG. 16) and a third connection electrode 1630 (see FIG. 16) may correspond to the source electrode SE and the drain electrode DE connected to the driving transistor T1, respectively. According to some embodiments, the third connection electrode 1630 (see FIG. 16) and a first connection electrode 1610 (see FIG. 16) may correspond to the source electrode SE and the drain electrode DE connected to the compensation transistor T3, respectively. According to some embodiments, the third connection electrode 1630 (see FIG. 16) and a first pixel connection electrode 1660 (see FIG. 16) may correspond to the source electrode SE and the drain electrode DE connected to the emission control transistor T6, respectively.

The fourth conductive layer 1600 (see FIG. 16) (e.g., the source electrode SE and the drain electrode DE) may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed as a single layer or multiple layers including the aforementioned material.

A first via insulating layer 121 may be located on the source electrode SE and the drain electrode DE. The first via insulating layer 121 may cover the source electrode SE and the drain electrode DE and may be located on the second interlayer insulating layer 116. The first via insulating layer 121 may be referred to as a first planarization layer providing a flat top surface.

The first via insulating layer 121 may include an organic insulating material. For example, the first via insulating layer 121 may include photoresist, benzocyclobutene (BCB), polyimide, hexamethyldisiloxane (HMDSO), polymethylmethacrylate (PMMA), polystyrene, a polymer derivative having a phenol-based group, acryl-based polymer, imide-based polymer, arylether-based polymer, amide-based polymer, fluorine-based polymer, p-xylene-based polymer, vinyl alcohol-based polymer, or a compound thereof.

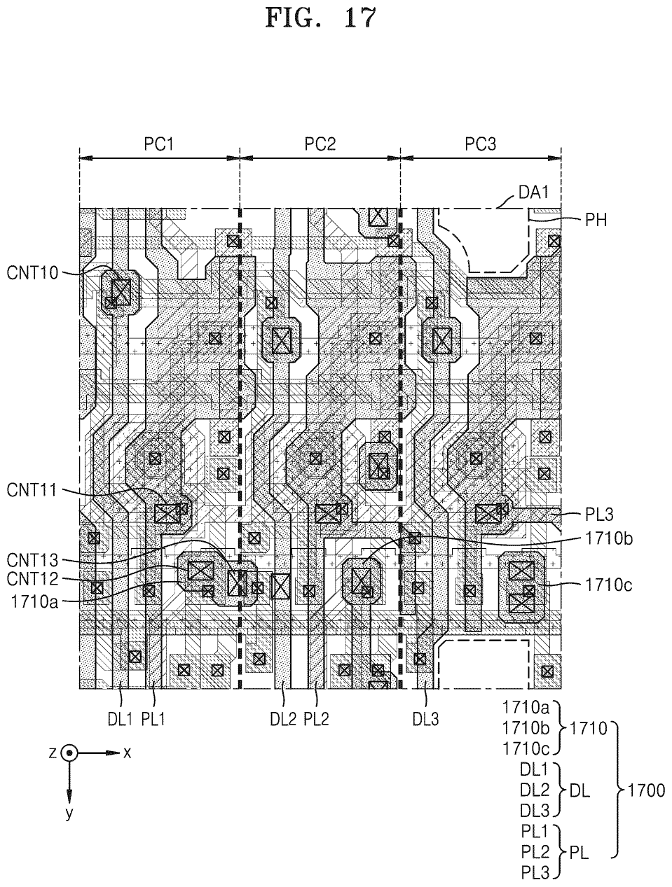

A fifth conductive layer 1700 (see FIG. 17) may be located on the first via insulating layer 121. For example, a second pixel connection electrode 1710 may be located on the first via insulating layer 121. The fifth conductive layer 1700 (see FIG. 17) (e.g., the second pixel connection electrode 1710) may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed as a single layer or multiple layers including the aforementioned material.

A second via insulating layer 123 may be located on the fifth conductive layer 1700 (see FIG. 17) (e.g., the second pixel connection electrode 1710). The second via insulating layer 123 may cover the fifth conductive layer 1700 (see FIG. 17) (e.g., the second pixel connection electrode 1710) and may be located on the first via insulating layer 121. The second via insulating layer 123 may be referred to as a second planarization layer providing a flat top surface.

The second via insulating layer 123 may include an organic insulating material. For example, the second via insulating layer 123 may include photoresist, BCB, polyimide, HMDSO, PMMA, polystyrene, a polymer derivative having a phenol-based group, acryl-based polymer, imide-based polymer, arylether-based polymer, amide-based polymer, fluorine-based polymer, p-xylene-based polymer, vinyl alcohol-based polymer, or a compound thereof.

The light-emitting element LED may be located on the second via insulating layer 123. The light-emitting element LED may include a pixel electrode 210, an intermediate layer 220, and a counter electrode 230 on the second via insulating layer 123. According to some embodiments, the light-emitting element LED may be electrically connected to the emission control transistor T6 of the pixel circuit PC by the second pixel connection electrode 1710.

The pixel electrode 210 may be a (semi-) transmissive electrode or a reflective electrode. For example, the pixel electrode 210 may include a reflective layer including Ag, Mg, Al, Pt, Pd, Au, Ni, Nd, Ir, Cr, or a compound thereof, and a transparent or semi-transparent electrode layer on the reflective layer. The transparent or semi-transparent electrode layer may include at least one of indium tin oxide (ITO), indium zinc oxide (IZO), zinc oxide (ZnOₓ), indium oxide (In₂O₃), indium gallium oxide (IGO), or aluminum zinc oxide (AZO). For example, the pixel electrode 210 may have a three-layer structure of ITO/Ag/ITO.

The pixel defining layer 130 may be located on the pixel electrode 210. An edge of the pixel electrode 210 may be covered by the pixel defining layer 130 and an inner portion of the pixel electrode 210 may overlap the intermediate layer 220 through a pixel opening 130OP of the pixel defining layer 130. In other words, the pixel defining layer 130 may define the pixel opening 130OP covering the edge of the pixel electrode 210 and exposing a portion of the pixel electrode 210. The pixel opening 130OP of the pixel defining layer 130 may define a light-emitting area EA of the light-emitting element LED.

Each of a plurality of the pixel electrodes 210 are formed corresponding to each light-emitting elements LED, whereas the counter electrode 230 may be formed corresponding to multiple light-emitting elements LED. In other words, the plurality of light-emitting elements LED may share the counter electrode 230, and a stack structure of the pixel electrode 210, the intermediate layer 220, and the counter electrode 230 may correspond to the light-emitting element LED.

The intermediate layer 220 may be located on the pixel electrode 210. The intermediate layer 220 may include an emission layer 222, a first functional layer 221 located below the emission layer 222, and a second functional layer 223 located on the emission layer 222. The emission layer 222 may have a shape patterned according to the pixel electrode 210. The emission layer 222 may include a high-molecular weight organic material or low-molecular weight organic material, which emit light of certain color. The first functional layer 221 may be a hole transport layer. Alternatively, the first functional layer 221 may include a hole injection layer and a hole transport layer. The second functional layer 223 may include an electron transport layer and/or an electron injection layer. The first functional layer 221 and/or the second functional layer 223 may be entirely located on the substrate 100. The first functional layer 221 and the second functional layer 223 may be each integrated to correspond to the plurality of light-emitting elements LED. According to some embodiments, the first functional layer 221 or the second functional layer 223 may be omitted.

The counter electrode 230 may be located on the intermediate layer 220. The counter electrode 230 may be a transparent electrode, a semi-transparent electrode, or a reflective electrode. For example, the counter electrode 230 may include Li, Ag, Mg, Al, Al—Li, Ca, Mg—In, Mg—Ag, ytterbium (Yb), Ag—Yb, ITO, IZO, or an any combination thereof. The counter electrode 230 may be integrated to correspond to the plurality of light-emitting elements LED.

The encapsulation layer 300 may be located on the light-emitting element LED. The encapsulation layer 300 may include at least one inorganic encapsulation layer and at least one organic encapsulation layer. According to some embodiments, FIG. 5 illustrates that the encapsulation layer 300 includes the first inorganic encapsulation layer 310, the organic encapsulation layer 320, and the second inorganic encapsulation layer 330.

The first inorganic encapsulation layer 310 and the second inorganic encapsulation layer 330 may each include an inorganic insulating material, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The first inorganic encapsulation layer 310 and second inorganic encapsulation layer 330 may each have a single layer or multilayer structure including the above inorganic insulating material.

The organic encapsulation layer 320 may relieve internal stress of the first inorganic encapsulation layer 310 and/or the second inorganic encapsulation layer 330. The organic encapsulation layer 320 may include a polymer-based material. Examples of the polymer-based material may include polyethylene terephthalate, polyethylene naphthalate, polycarbonate, polyimide, polyethylene sulfonate, polyoxymethylene, polyarylate, hexamethyldisiloxane, acrylic resins (e.g., polymethyl methacrylate, polyacrylic acid, etc.), and any combination thereof.

The organic encapsulation layer 320 may be formed by coating a material that has flowability and contains monomers and then combining the monomers by using heat or light such as ultraviolet rays to form a polymer. Alternatively, the organic encapsulation layer 320 may be formed by coating a polymer material.

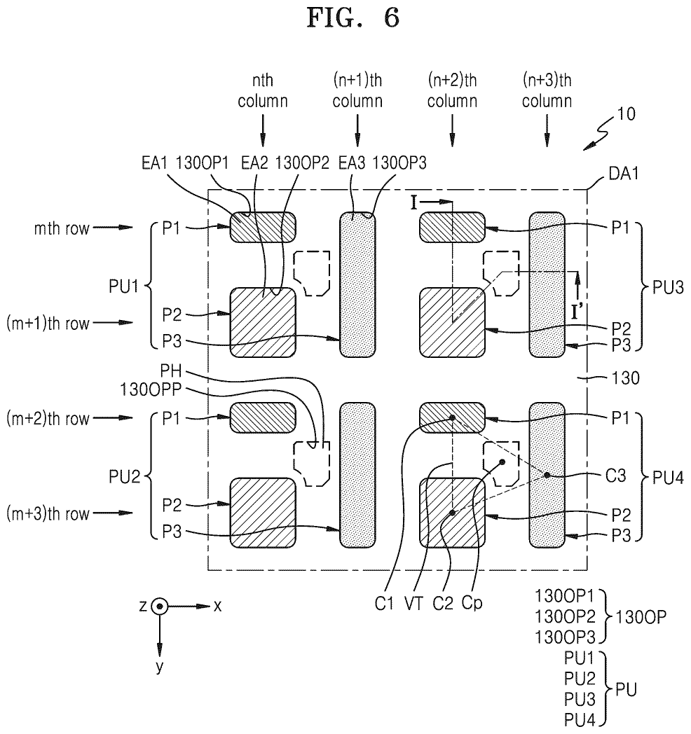

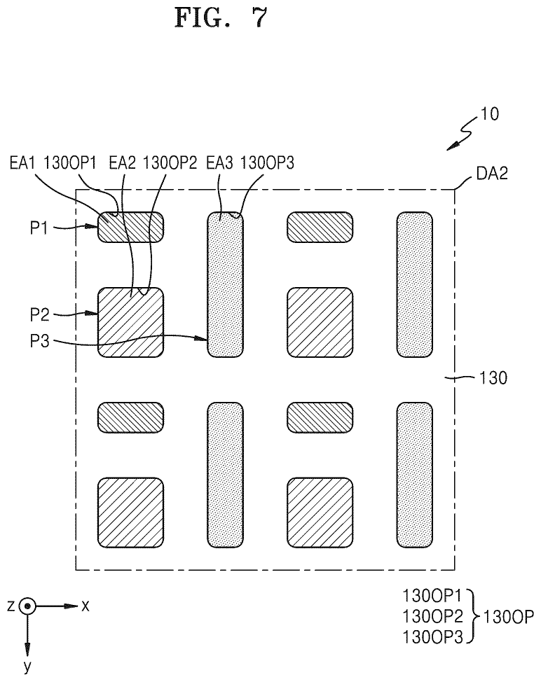

FIG. 6 is a schematic plan view of an arrangement of light-emitting areas EA1, EA2, and EA3, and hole areas PH in the first display area DA1 of the display panel 10 according to some embodiments. FIG. 7 is a schematic plan view of an arrangement of light-emitting areas EA1, EA2, and EA3, in the second display area DA2 of the display panel 10 according to some embodiments.

A first pixel P1, a second pixel P2, and a third pixel P3 that emit light of different colors may be arranged in each of the first display area DA1 and the second display area DA2. For example, the first pixel P1 may emit red light, the second pixel P2 may emit green light, and the third pixel P3 may emit blue light. However, the embodiments according to the present disclosure are not limited thereto, and various modifications may be possible, such as, for example, the first pixel P1 emitting blue light, the second pixel P2 emitting green light, and the third pixel P3 emitting red light.

The first pixel P1, the second pixel P2, and the third pixel P3 adjacent to each other may constitute a unit pixel PU. The unit pixel PU may be arranged along a first direction (e.g., +x direction or row direction) and a second direction (e.g., +y direction or column direction) in a plan view. For example, each of a first unit pixel PU1, a second unit pixel PU2, a third unit pixel PU3, and a fourth unit pixel PU4 arranged adjacent to each other may include the first pixel P1, the second pixel P2, and the third pixel P3. For example, the first unit pixel PU1 and the second unit pixel PU2 may be arranged adjacently along the second direction (e.g., the +y direction), the third unit pixel PU3 and the fourth unit pixel PU4 may be arranged adjacently along the second direction (e.g., the +y direction), the first unit pixel PU1 and the third unit pixel PU3 may be arranged adjacently along the first direction (e.g., the +x direction), and the second unit pixel PU2 and the fourth unit pixel PU4 may be arranged adjacently along the first direction (e.g., the +x direction).

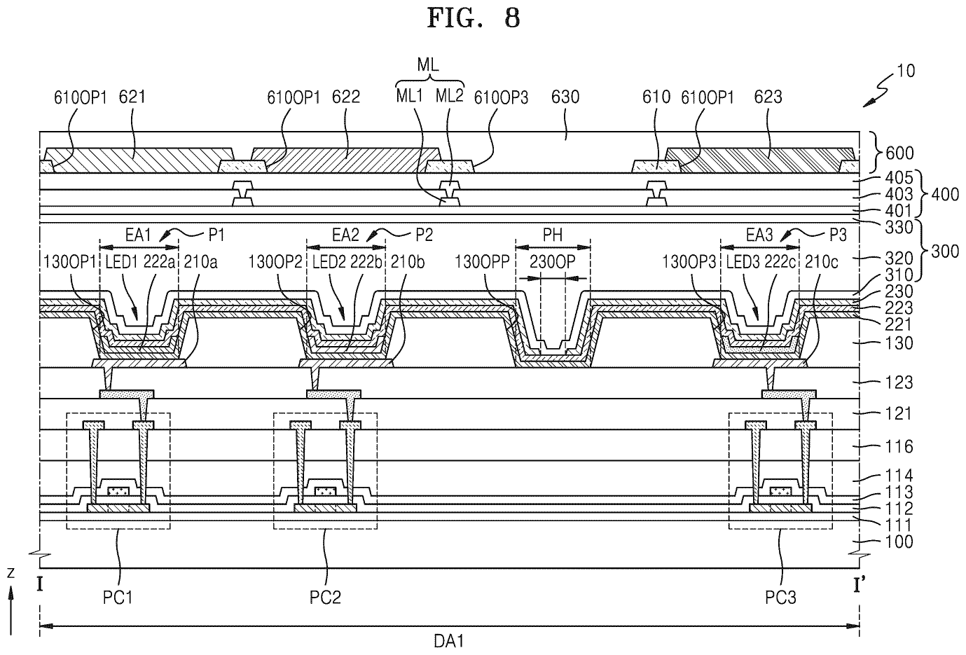

FIGS. 6 and 7 illustrate a first light-emitting area EA1 of a first light-emitting element LED1 (see FIG. 8) of the first pixel P1, a second light-emitting area EA2 of a second light-emitting element LED2 (see FIG. 8) of the second pixel P2, and a third light-emitting area EA3 of a third light-emitting element LED3 (see FIG. 8) of the third pixel P3. Each of the first to third light-emitting areas EA1, EA2, and EA3 may be defined by the pixel opening 130OP of the pixel defining layer 130. For example, the first light-emitting area EA1 may be defined by a first pixel opening 130OP1 of the pixel defining layer 130, the second light-emitting area EA2 may be defined by a second pixel opening 130OP2 of the pixel defining layer 130, and the third light-emitting area EA3 may be defined by a third pixel opening 130OP3 of the pixel defining layer 130.

Referring to FIGS. 6 and 7, an arrangement of the first light-emitting area EA1, the second light-emitting area EA2, and the third light-emitting area EA3 in the first display area DA1 and the second display area DA2 may be the same. Accordingly, for convenience of explanation, the arrangement of the first light-emitting area EA1, the second light-emitting area EA2, and the third light-emitting area EA3 will be explained based on the first display area DA1 with reference to FIG. 6.

The first light-emitting area EA1 and the second light-emitting area EA2 may be arranged along the second direction (e.g., the +y direction), and the third light-emitting area EA3 may be arranged along the first direction (e.g., the +x direction) from each of the first light-emitting area EA1 and the second light-emitting area EA2.

According to some embodiments, a width (or length) of the third light-emitting area EA3 in the second direction (e.g., +y direction) may be greater than a width (or length) of the first light-emitting area EA1 in the second direction (e.g., +y direction) and/or a width (or length) of the second light-emitting area EA2 in the second direction (e.g., +y direction).

In a nth column (n is a natural number), the first light-emitting areas EA1 and the second light-emitting areas EA2 may be alternately arranged along the second direction (e.g., the +y direction). For example, the first light-emitting area EA1 of the first unit pixel PU1, the second light-emitting area EA2 of the first unit pixel PU1, the first light-emitting area EA1 of the second unit pixel PU2, and the second light-emitting area EA2 of the second unit pixel PU2 may be arranged in sequence along the second direction (e.g., the +y direction).

In a (n+1)th (n is a natural number) column, the third light-emitting areas EA3 may be repeatedly arranged along the second direction (e.g., the +y direction). For example, the third light-emitting area EA3 of the first unit pixel PU1 and the third light-emitting area EA3 of the second unit pixel PU2 may be arranged along the second direction (e.g., the +y direction).

In a (n+2)th (n is a natural number) column, the first light-emitting areas EA1 and the second light-emitting areas EA2 may be alternately arranged along the second direction (e.g., the +y direction). For example, the first light-emitting area EA1 of the third unit pixel PU3, the second light-emitting area EA2 of the third unit pixel PU3, the first light-emitting area EA1 of the fourth unit pixel PU4, and the second light-emitting area EA2 of the fourth unit pixel PU4 may be arranged in sequence along the second direction (e.g., the +y direction).

In a (n+3)th (n is a natural number) column, the third light-emitting areas EA3 may be repeatedly arranged along the second direction (e.g., the +y direction). For example, the third light-emitting area EA3 of the third unit pixel PU3 and the third light-emitting area EA3 of the fourth unit pixel PU4 may be arranged along the second direction (e.g., the +y direction).

In a mth row (m is a natural number), the first light-emitting areas EA1 and the third light-emitting areas EA3 may be alternately arranged along the first direction (e.g., the +x direction). For example, the first light-emitting area EA1 of the first unit pixel PU1, a portion of the third light-emitting area EA3 of the first unit pixel PU1, the first light-emitting area EA1 of the third unit pixel PU3, and a portion of the third light-emitting area EA3 of the third unit pixel PU3 may be arranged in sequence along the first direction (e.g., the +x direction).

In a (m+1)th row (m is a natural number), the second light-emitting areas EA2 and the third light-emitting areas EA3 may be alternately arranged along the first direction (e.g., the +x direction). For example, the second light-emitting area EA2 of the first unit pixel PU1, a portion of the third light-emitting area EA3 of the first unit pixel PU1, the second light-emitting area EA2 of the third unit pixel PU3, and a portion of the third light-emitting area EA3 of the third unit pixel PU3 may be arranged in sequence along the first direction (e.g., the +x direction).

The single third light-emitting area EA3 may be arranged across the mth row and the (m+1)th row. For example, a portion of the third light-emitting area EA3 of the first unit pixel PU1 may be arranged in the mth row, and a remaining portion of the third light-emitting area EA3 of the first unit pixel PU1 may be arranged in the (m+1)th row. For example, a portion of the third light-emitting area EA3 of the third unit pixel PU3 may be arranged in the mth row, and a remaining portion of the third light-emitting area EA3 of the third unit pixel PU3 may be arranged in the (m+1)th row.

In a (m+2)th row (m is a natural number), the first light-emitting areas EA1 and the third light-emitting area EA3 may be alternately arranged along the first direction (e.g., the +x direction). For example, the first light-emitting area EA1 of the second unit pixel PU2, a portion of the third light-emitting area EA3 of the second unit pixel PU2, the first light-emitting area EA1 of the fourth unit pixel PU4, and a portion of the third light-emitting area EA3 of the fourth unit pixel PU4 may be arranged in sequence along the first direction (e.g., the +x direction).

In a (m+3)th row (m is a natural number), the second light-emitting areas EA2 and the third light-emitting areas EA3 may be alternately arranged along the first direction (e.g., the +x direction). For example, the second light-emitting area EA2 of the second unit pixel PU2, a portion of the third light-emitting area EA3 of the second unit pixel PU2, the second light-emitting area EA2 of the fourth unit pixel PU4, and a portion of the third light-emitting area EA3 of the fourth unit pixel PU4 may be arranged in sequence along the first direction (e.g., the +x direction).

The single third light-emitting area EA3 may be arranged across the (m+2)th row and the (m+3)th row. For example, a portion of the third light-emitting area EA3 of the second unit pixel PU2 may be arranged in the (m+2)th row, and a remaining portion of the third light-emitting area EA3 of the second unit pixel PU2 may be arranged in the (m+3)th row. For example, a portion of the third light-emitting area EA3 of the fourth unit pixel PU4 may be arranged in the (m+2)th row, and a remaining portion of the third light-emitting area EA3 of the fourth unit pixel PU4 may be arranged in the (m+3)th row.

Each of the first light-emitting area EA1, the second light-emitting area EA2, and the third light-emitting area EA3 may have a polygonal shape. For example, the first light-emitting area EA1, the second light-emitting area EA2, and the third light-emitting area EA3 may have a rectangular shape. In this specification, a polygon includes a polygon with rounded vertices. According to some embodiments, the first light-emitting area EA1, the second light-emitting area EA2, and the third light-emitting area EA3 may have a circular or oval shape.

A size (or area) of the first light-emitting area EA1, a size (or area) of the second light-emitting area EA2, and a size (or area) of the third light-emitting area EA3 may be different from each other. For example, the size (or area) of the first light-emitting area EA1 may be smaller than the size (or area) of the second light-emitting area EA2 and the size (or area) of the third light-emitting area EA3, and the size (or area) of the third light-emitting area EA3 may be larger than the size (or area) of the second light-emitting area EA2. According to some embodiments, the size (or area) of the first light-emitting area EA1, the size (or area) of the second light-emitting area EA2, and the size (or area) of the third light-emitting area EA3 may be the same (or substantially the same), and various modifications are possible.

As illustrated in FIG. 6, in the first display area DA1, a plurality of hole areas PH may be positioned regularly at regular intervals. The hole area PH may be defined by an opening 130OPP of the pixel defining layer 130. The hole area PH may be located between the first light-emitting area EA1, the second light-emitting area EA2, and the third light-emitting area EA3 of one unit pixel in the first display area DA1. For example, in a plan view, a center Cp of the hole area PH may be located within an imaginary triangle VT defined by connecting a center C1 of the first light-emitting area EA1, a center C2 of the second light-emitting area EA2, and a center C3 of the third light-emitting area EA3. According to some embodiments, the first light-emitting area EA1, the hole area PH, and the second light-emitting area EA2 may be arranged staggered along the second direction (e.g., the +y direction).

The hole area PH may be located between adjacent pixels PX and may not overlap light-emitting elements LED. The pixel circuits, the circuit elements constituting the pixel circuit and/or the wires may not be located in the hole area PH.

The hole area PH does not denote an actual hole formed in the substrate 100 or an insulating layer, but may be defined by a region having a certain area and seen in a hole-like shape, as the circuit elements constituting the pixel circuits and/or wires (e.g., signal lines) connected to the pixel circuits are not arranged on the substrate 100, when viewed in a direction perpendicular to the upper surface of the substrate 100, according to the arrangement of the circuit elements and wires on the substrate 100.

According to some embodiments, in a plan view, the hole area PH may have a closed curve shape. According to some embodiments, in a plan view, the hole area PH may be spaced apart from each of the first to third light-emitting areas EA1, EA2, and EA3.

As illustrated in FIG. 7, the second display area DA2 may include only the first light-emitting area EA1, the second light-emitting area EA2, and the third light-emitting area EA3, and may not include the hole area PH.

FIG. 8 is a schematic cross-sectional view of the display panel 10 in a first display area DA1 according to some embodiments, and is a cross-sectional view taken along the line I-I′ of the display panel 10 in the first display area DA1 of FIG. 6.

Because each of the first pixel circuit PC1, the second pixel circuit PC2, and the third pixel circuit PC3 of FIG. 8 may have the same (or substantially the same) structure as the pixel circuit PC described with reference to FIG. 5, some redundant description may be omitted. Because each of the first light-emitting element LED1, the second light-emitting element LED2, and the third light-emitting element LED3 of FIG. 8 may have the same (or substantially the same) structure as the light-emitting element LED described with reference to FIG. 5, some redundant description may be omitted.

Referring to FIG. 8, the first pixel P1, the second pixel P2, and the third pixel P3 may be located on a substrate 100.

The first pixel P1 may include the first light-emitting element LED1 and the first pixel circuit PC1, the second pixel P2 may include the second light-emitting element LED2 and the second pixel circuit PC2, and the third pixel P3 may include the third light-emitting element LED3 and the third pixel circuit PC3.

The first pixel circuit PC1 may be located between the substrate 100 and the first light-emitting element LED1 and may be electrically connected to the first light-emitting element LED1. The second pixel circuit PC2 may be arranged such that it is placed between the substrate 100 and the second light-emitting element LED2 and may be electrically connected to the second light-emitting element LED2. The third pixel circuit PC3 may be located between the substrate 100 and the third light-emitting element LED3 and may be electrically connected to the third light-emitting element LED3.

The first light-emitting element LED1, the second light-emitting element LED2, and the third light-emitting element LED3 may emit light of different colors. For example, the first light-emitting element LED1 may emit red light, the second light-emitting element LED2 may emit green light, and the third light-emitting element LED3 may emit blue light. However, the embodiments according to the present disclosure are not limited thereto, and various modifications may be possible, such as, for example, the first light-emitting element LED1 emitting blue light, the second light-emitting element LED2 emitting green light, and the third light-emitting element LED3 emitting red light.

The first light-emitting element LED1 may include a first pixel electrode 210a, the intermediate layer 220 (see FIG. 5), and the counter electrode 230. The second light-emitting element LED2 may include a second pixel electrode 210b, the intermediate layer 220 (see FIG. 5), and the counter electrode 230. The third light-emitting element LED3 may include a third pixel electrode 210c, the intermediate layer 220 (see FIG. 5), and the counter electrode 230. The first pixel electrode 210a, the second pixel electrode 210b, and the third pixel electrode 210c may be spaced apart from each other.

The intermediate layer 220 (see FIG. 5) of the first light-emitting element LED1 may include the first functional layer 221, a first emission layer 222a, and the second functional layer 223. The intermediate layer 220 (see FIG. 5) of the second light-emitting element LED2 may include a first functional layer 221, a second emission layer 222b, and a second functional layer 223. The intermediate layer 220 (see FIG. 5) of the third light-emitting element LED3 may include the first functional layer 221, a third emission layer 222c, and the second functional layer 223. According to some embodiments, the first emission layer 222a may be patterned corresponding to the first pixel electrode 210a, the second emission layer 222b may be patterned corresponding to the second pixel electrode 210b, and the third emission layer 222c may be patterned corresponding to the third pixel electrode 210c. Each of the first emission layer 222a, the second emission layer 222b, and the third emission layer 222c may include a high-molecular weight or low-molecular weight organic material emitting light of a certain color. According to some embodiments, the first emission layer 222a, the second emission layer 222b, and the third emission layer 222c may emit light of different colors.

The pixel defining layer 130 may be located on the first pixel electrode 210a, the second pixel electrode 210b, and the third pixel electrode 210c. The pixel defining layer 130 may include the first pixel opening 130OP1 exposing a portion of the first pixel electrode 210a, the second pixel opening 130OP2 exposing a portion of the second pixel electrode 210b, and the third pixel opening 130OP3 exposing a portion of the third pixel electrode 210c. The pixel defining layer 130 may further include the opening 130OPP defining the hole area PH. The hole area PH may be an area where light-shielding elements, such as the first to third pixel circuits PC1, PC2, and PC3 and/or wires connected to the first to third pixel circuits PC1, PC2, and PC3, are not arranged.

The first pixel electrode 210a, the second pixel electrode 210b, and the third pixel electrode 210c may be arranged to overlap the first pixel opening 130OP1, the second pixel opening 130OP2, and the third pixel opening 130OP3, respectively. A first emission layer 222a, a second emission layer 222b, and a third emission layer 222c may be located within the first pixel opening 130OP1, the second pixel opening 130OP2, and the third pixel opening 130OP3, respectively. The first functional layer 221 and the second functional layer 223 are integrally provided across the first to third light-emitting elements LED1, LED2, and LED3 and may be arranged in the hole area PH.

According to some embodiments, the counter electrode 230 may include an opening 230OP in a region overlapping the hole area PH. A transmittance of the hole area PH may be relatively improved by the opening 230OP of the counter electrode 230. A size (or width) of the opening 230OP of the counter electrode 230 is shown to be smaller than a size (or width) of the opening 130OPP defining the hole area PH of the pixel defining layer 130, but is not limited thereto. For example, the size (or width) of the opening 230OP of the counter electrode 230 may be equal to or larger than the size (or width) of the opening 130OPP defining the hole area PH of the pixel defining layer 130.

The pixel defining layer 130 is a colored opaque light-blocking insulating layer and for example, may be black. For example, the pixel defining layer 130 may include a polyimide (PI)-based binder and a pigment in which red, green, and blue pigments are mixed. Alternatively, the pixel defining layer 130 may include a cardo-based binder resin and a mixture of a lactam black pigment and a blue pigment. For example, the pixel defining layer 130 may include carbon black. The pixel defining layer 130 prevents (or reduce) reflection of external light, and the pixel defining layer 130 may relatively improve the contrast of the display panel 10.

The encapsulation layer 300 may encapsulate the first light-emitting element LED1, the second light-emitting element LED2, and the third light-emitting element LED3.

The touch-screen layer 400 includes a touch electrode, and the touch electrode may include a touch conductive layer ML. The touch electrode may include the touch electrode having a mesh structure surrounding the light-emitting areas of the first light-emitting element LED1, the second light-emitting element LED2, and the third light-emitting element LED3 in a plan view.

According to some embodiments, the touch conductive layer ML may include a first touch conductive layer ML1 and a second touch conductive layer ML2 on the first touch conductive layer ML1. The first touch conductive layer ML1 and the second touch conductive layer ML2 may be connected through a contact hole. The first touch conductive layer ML1 and the second touch conductive layer ML2 may be arranged so as not to overlap the first light-emitting area EA1, the second light-emitting area EA2, and the third light-emitting area EA3. According to some embodiments, the touch conductive layer ML may include one of the first touch conductive layer ML1 and the second touch conductive layer ML2. The touch conductive layer ML may include molybdenum (Mo), mendelevium (Mb), silver (Ag), titanium (Ti), copper (Cu), aluminum (Al), or an alloy thereof. The electrode of the touch-screen layer 400, for example, the touch conductive layer ML, may overlap the light-shielding layer 610.

The touch-screen layer 400 may include a first touch insulating layer 401 on the encapsulation layer 300, a second touch insulating layer 403 on the first touch insulating layer 401, and a third touch insulating layer 405 on the second touch insulating layer 403. The first touch conductive layer ML1 may be located between the first touch insulating layer 401 and the second touch insulating layer 403, and the second touch conductive layer ML2 may be located between the second touch insulating layer 403 and the third touch insulating layer 405.

The first to third touch insulating layers 401, 403, and 405 may include an inorganic insulating material and/or an organic insulating material. According to some embodiments, the first touch insulating layer 401 and the second touch insulating layer 403 may include an inorganic insulating material, and the third touch insulating layer 405 may include an organic insulating material.

According to some embodiments, the anti-reflection layer 600 may include the light-shielding layer 610, a first color filter 621, a second color filter 622, and a third color filter 623.

The light-shielding layer 610 may include first openings 610OP1 that overlap the first light-emitting area EA1, the second light-emitting area EA2, and the third light-emitting area EA3, respectively. Color filters may be arranged in each of the first openings 610OP1 of the light-shielding layer 610. For example, the first color filter 621 may be arranged in the first opening 610OP1 of a light-shielding layer 610 corresponding to the first light-emitting area EA1, the second color filter 622 may be arranged in the first opening 610OP1 of the light-shielding layer 610 corresponding to the second light-emitting area EA2, and the third color filter 623 may be arranged in the first opening 610OP1 of the light-shielding layer 610 corresponding to a third light-emitting area EA3.

According to some embodiments, the first color filter 621, the second color filter 622, and the third color filter 623 may have colors corresponding to the colors of light emitted from the first light-emitting element LED1, the second light-emitting element LED2, and the third light-emitting element LED3, respectively. For example, when the first light-emitting element LED1 emits red light, the first color filter 621 may be a red color filter, when the second light-emitting element LED2 emits green light, the second color filter 622 may be a green color filter, and when the third light-emitting element LED3 emits blue light, the third color filter 623 may be a blue color filter. The light-shielding layer 610 is located between adjacent color filters and may be located to surround the edge of each pixel P1, P2, and P3.

The widths of the first openings 610OP1 of the light-shielding layer 610 may be equal to or greater than each of the width of the first light-emitting area EA1, the width of the second light-emitting area EA2, and the width of the third light-emitting area EA3.

The light-shielding layer 610 may include the third opening 610OP3 corresponding to (or overlapping) the hole area PH. According to some embodiments, the first to third color filters 621, 622, and 623 may not be positioned in the third opening 610OP3 of the light-shielding layer 610, and a portion of the overcoated layer 630 may be positioned therein. According to some embodiments, the overcoated layer 630 may fill the third opening 610OP3 of the light-shielding layer 610 and entirely cover the light-shielding layer 610 and the first to third color filters 621, 622, and 623.

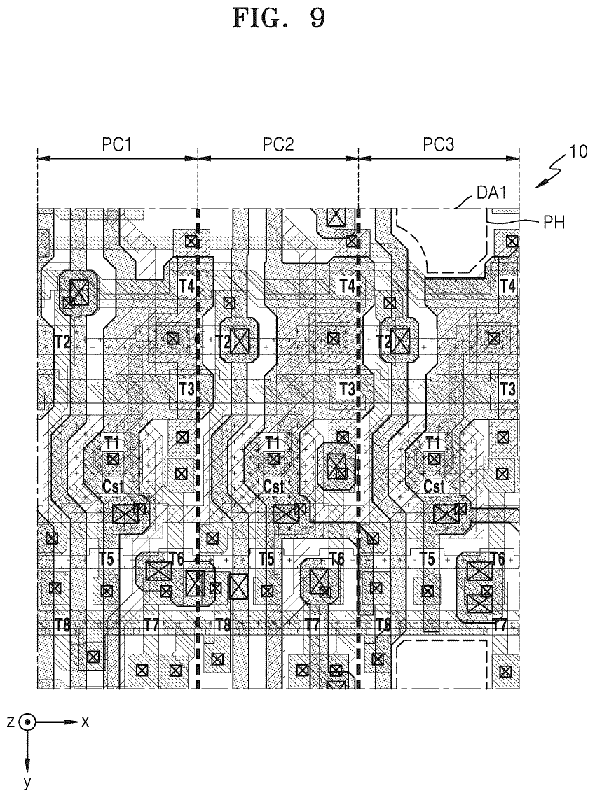

FIG. 9 is a plan view of the first pixel circuit PC1, the second pixel circuit PC2, and the third pixel circuit PC3 arranged in the first display area DA1 of the display panel 10 according to some embodiments. The first pixel circuit PC1, the second pixel circuit PC2, and the third pixel circuit PC3 illustrated in FIG. 9 may be arranged along the ith row. For example, the first pixel circuit PC1, the second pixel circuit PC2, and the third pixel circuit PC3 may be arranged adjacent to each other along the first direction (e.g., the +x direction).

Referring to FIG. 9, each of the first pixel circuit PC1, the second pixel circuit PC2, and the third pixel circuit PC3 may include a plurality of transistors and a capacitor. According to some embodiments, FIG. 9 illustrates the first pixel circuit PC1, the second pixel circuit PC2, and the third pixel circuit PC3 each including the eight transistors T1, T2, T3, T4, T5, T6, T7, and T8 and the first capacitor Cst, which are described above with reference to FIG. 4.

The driving transistor T1 may overlap the first capacitor Cst. Switching transistors (e.g., the transistors T2 to T8) may be arranged at an upper side and/or a lower side in a plan view, based on the driving transistor T1 and/or the first capacitor Cst. According to some embodiments, FIG. 9 illustrates, in a plan view, the data write transistor T2, the compensation transistor T3, and the first initialization transistor T4 arranged at the upper side (e.g., in a third direction or −y direction) of the driving transistor T1 and/or the first capacitor Cst. The operation control transistor T5, the emission control transistor T6, the second initialization transistor T7, and the bias transistor T8 may be arranged, in a plan view, at the lower side (e.g., in the second direction or the +y direction) of the driving transistor T1 and/or the first capacitor Cst. In this specification, the third direction (e.g., the −y direction) may refer to a direction opposite to the second direction (e.g., the +y direction).

As illustrated in FIG. 9, in a plan view, the hole area PH may be arranged to be spaced apart from circuit elements constituting the first pixel circuit PC1, wires electrically connected to the first pixel circuit PC1, circuit elements constituting the second pixel circuit PC2, wires electrically connected to the second pixel circuit PC2, circuit elements constituting the third pixel circuit PC3, and wires electrically connected to the third pixel circuit PC3. In other words, the hole area PH may not overlap the circuit elements constituting each of the first pixel circuit PC1, the second pixel circuit PC2, and the third pixel circuit PC3 and the wires electrically connected to each of the first pixel circuit PC1, the second pixel circuit PC2, and the third pixel circuit PC3.

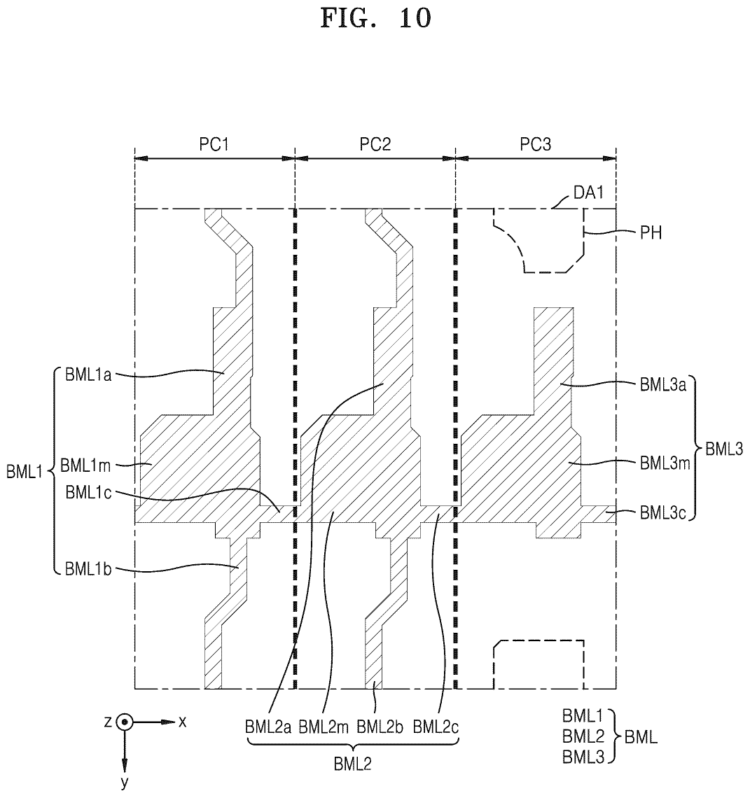

FIGS. 10 to 17 are plan views according to a stacking order of components constituting the first to third pixel circuits PC1, PC2, and PC3 illustrated in FIG. 9.

Referring to FIG. 10, the blocking metal layer BML may be located on the substrate 100 (see FIG. 5). According to some embodiments, the blocking metal layer BML may be located between the upper surface of the substrate 100 (see FIG. 5) and the driving transistor T1 (see FIG. 9) of the first pixel circuit PC1, between the upper surface of the substrate 100 (see FIG. 5) and the driving transistor T1 (see FIG. 9) of the second pixel circuit PC2, and between the upper surface of the substrate 100 (see FIG. 5) and the driving transistor T1 (see FIG. 9) of the third pixel circuit PC3.

The blocking metal layer BML may include a first blocking metal portion BML1, a second blocking metal portion BML2, and a third blocking metal portion BML3 corresponding to the first pixel circuit PC1, the second pixel circuit PC2, and the third pixel circuit PC3, respectively. The first blocking metal portion BML1, the second blocking metal portion BML2, and the third blocking metal portion BML3 may be connected as one.

The first blocking metal portion BML1 may include a first main portion BML1m, a first-1 branch portion BML1a connected to the first main portion BML1m and extending in the third direction (e.g., in the −y direction) from the first main portion BML1m, a first-2 branch portion BML1b connected to the first main portion BML1m and extending in the second direction (e.g., in the +y direction) from the first main portion BML1m, and a first-3 branch portion BML1c connected to the first main portion BML1m and extending in the first direction (e.g., in the +x direction) from the first main portion BML1m.

A width (e.g., maximum width) along the first direction (e.g., the +x direction) of the first main portion BML1m may be greater than a width (e.g., maximum width) along the first direction (e.g., the +x direction) of the first-1 branch portion BML1a and a width (e.g., maximum width) along the first direction (e.g., +x direction) of the first-2 branch portion BML1b. The first main portion BML1m may overlap the driving transistor T1 (see FIG. 9) of the first pixel circuit PC1.

The first-3 branch portion BML1c may connect the first main portion BML1m of the first blocking metal portion BML1 and the second main portion BML2m of the second blocking metal portion BML2 described below.

The second blocking metal portion BML2 may include a second main portion BML2m, a second-1 branch portion BML2a connected to the second main portion BML2m and extending in the third direction (e.g., the −y direction) from the second main portion BML2m, a second-2 branch portion BML2b connected to the second main portion BML2m and extending in the second direction (e.g., the +y direction) from the second main portion BML2m, and a second-3 branch portion BML2c connected to the second main portion BML2m and extending in the first direction (e.g., a +x direction) from the second main portion BML2m.

A width (e.g., maximum width) along the first direction (e.g., the +x direction) of the second main portion BML2m may be greater than a width (e.g., maximum width) along the first direction (e.g., the +x direction) of the second-1 branch portion BML2a and the width (e.g., maximum width) along the first direction (e.g., +x direction) of the second-2 branch portion BML2b. The second main portion BML2m may overlap the driving transistor T1 (see FIG. 9) of the second pixel circuit PC2.

The second-3 branch portion BML2c may connect the second main portion BML2m of the second blocking metal portion BML2 and the third main portion BML3m of the third blocking metal portion BML3 described below.

The third blocking metal portion BML3 may include the third main portion BML3m, a third-1 branch portion BML3a connected to the third main portion BML3m and extending in the third direction (e.g., the −y direction) from the third main portion BML3m, and a third-2 branch portion BML3c connected to the third main portion BML3m and extending in the first direction (e.g., the +x direction) from the third main portion BML3m.

A width (e.g., maximum width) along the first direction (e.g., +x direction) of the third main portion BML3m may be greater than a width (e.g., maximum width) along the first direction (e.g., +x direction) of the third-1 branch portion BML3a. The third main part BML3m may overlap the driving transistor T1 (see FIG. 9) of the third pixel circuit PC3.

A length along the third direction (e.g., the −y direction) of the third-1 branch portion BML3a may be smaller than a length along the third direction (e.g., the −y direction) of the first-1 branch portion BML1a and a length along the third direction (e.g., the −y direction) of the second-1 branch portion BML2a.

According to some embodiments, the third blocking metal portion BML3 corresponding to the third pixel circuit PC3 may be spaced apart from the hole area PH in a plan view. According to some embodiments, the length of the third-1 branch portion BML3a along the third direction (e.g., the −y direction) is formed to be smaller than the length of the first-1 branch portion BML1a along the third direction (e.g., the −y direction) and the length of the second-1 branch portion BML2a along the third direction (e.g., the −y direction), so that the blocking metal layer BML may be spaced apart from the hole area PH in a plan view.

The buffer layer 111 (see FIG. 5) may be located on the blocking metal layer BML.

Referring to FIG. 11, a first semiconductor layer 1100 may be located on the blocking metal layer BML. For example, the buffer layer 111 (see FIG. 5) may be located on the blocking metal layer BML, and the first semiconductor layer 1100 may be located on the buffer layer 111 (see FIG. 5). The first semiconductor layer 1100 may include a first semiconductor pattern 1110 and a second semiconductor pattern 1120. The first semiconductor pattern 1110 and the second semiconductor pattern 1120 may be located on a same layer (e.g., the buffer layer 111).

Each of the first to third pixel circuits PC1, PC2, and PC3 may include the first semiconductor pattern 1110 and the second semiconductor pattern 1120.

The first semiconductor pattern 1110 may include the driving semiconductor layer A1 of the driving transistor T1 (see FIG. 9), a semiconductor layer (hereinafter, referred to as a data write semiconductor layer A2) of the data write transistor T2 (see FIG. 9), a semiconductor layer (hereinafter, referred to as an operation control semiconductor layer A5) of the operation control transistor T5 (see FIG. 9), a semiconductor layer (hereinafter referred to as an emission control semiconductor layer A6) of the emission control transistor T6 (see FIG. 9), and a semiconductor layer (hereinafter, referred to as a second initialization semiconductor layer A7) of the second initialization transistor T7 (see FIG. 9). The second semiconductor pattern 1120 may include a semiconductor layer (hereinafter, referred to as a bias semiconductor layer A8) of the bias transistor T8 (see FIG. 9).

The first semiconductor layer 1100 (e.g., the first semiconductor pattern 1110 and the second semiconductor pattern 1120) may include a silicon semiconductor material. For example, the first semiconductor layer 1100 may include amorphous silicon or polysilicon. For example, the first semiconductor layer 1100 may include polysilicon crystallized at low temperature.

The first gate insulating layer 112 (see FIG. 5) may be located on the first semiconductor layer 1100.

Referring to FIG. 12, a first conductive layer 1200 may be located on the first semiconductor layer 1100 (see FIG. 11). For example, the first gate insulating layer 112 (see FIG. 5) may be located on the first semiconductor layer 1100 (see FIG. 11), and the first conductive layer 1200 may be located on the first gate insulating layer 112 (see FIG. 5). The first conductive layer 1200 may include a first conductive pattern 1 1210, the scan line GWL, the emission control line EML, and the second initialization control line GBL. The first conductive pattern 1210, the scan line GWL, the emission control line EML, and the second initialization control line GBL may be located on a same layer (e.g., the first gate insulating layer 112 (see FIG. 5)).

The first conductive pattern 1210, the scan line GWL, the emission control line EML, and the second initialization control line GBL may include a same material. Each of the first conductive pattern 1210, the scan line GWL, the emission control line EML, and the second initialization control line GBL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed as a single layer or multiple layers including the aforementioned material.

Each of the first conductive pattern 1210, the scan line GWL, and the emission control line EML may include a gate electrode overlapping the first semiconductor pattern 1110. The second initialization control line GBL may include a gate electrode overlapping the second semiconductor pattern 1120.

The first conductive pattern 1210 may be arranged in each of the first to third pixel circuits PC1, PC2, and PC3 and may have an isolated shape. The first conductive pattern 1210 may include the driving gate electrode G1 of the driving transistor T1. The driving semiconductor layer A1 may include a channel region overlapping the first conductive pattern 1210 that is the driving gate electrode G1, and a source region and a drain region arranged on both sides of the channel region. Referring to FIGS. 10 and 11, the channel region of the driving semiconductor layer A1 of the first pixel circuit PC1 may overlap a portion of the first blocking metal portion BML1 (e.g., the first main portion, BML1m), the channel region of the driving semiconductor layer A1 of the second pixel circuit PC2 may overlap a portion of the second blocking metal portion BML2 (e.g., the second main portion, BML2m), and the channel region of the driving semiconductor layer A1 of the third pixel circuit PC3 may overlap a portion of the third blocking metal portion BML3 (e.g., the third main portion, BML3m). Referring to FIG. 11, a shape of the channel region of the driving semiconductor layer A1 of each of the first to third pixel circuits PC1, PC2, and PC3 may have a shape bent multiple times (e.g., an omega shape).

As an example, the first conductive pattern 1210 may include the lower electrode CE1 of the first capacitor Cst. The first conductive pattern 1210 may include the driving gate electrode G1 and/or the lower electrode CE1 of the first capacitor Cst.

The scan line GWL may extend through the first pixel circuit PC1, the second pixel circuit PC2, and the third pixel circuit PC3 in the first direction (e.g., the +x direction). The scan line GWL may include a data write gate electrode G2 of each of the data write transistors T2 of the first to third pixel circuits PC1, PC2, and PC3. The data write semiconductor layer A2 may include a channel region overlapping the data write gate electrode G2 of the data write transistor T2, and a source region and a drain region arranged on both sides of the channel region.

The emission control line EML may extend through the first pixel circuit PC1, the second pixel circuit PC2, and the third pixel circuit PC3 in the first direction (e.g., the +x direction). The emission control line EML may include an operation control gate electrode G5 of the operation control transistor T5 and an emission control gate electrode G6 of the emission control transistor T6 of each of the first to third pixel circuits PC1, PC2, and PC3. The operation control semiconductor layer A5 may include a channel region overlapping the operation control gate electrode G5, and a source region and a drain region arranged on both sides of the channel region. The emission control semiconductor layer A6 may include a channel region overlapping the emission control gate electrode G6, and a source region and a drain region arranged on both sides of the channel region.

The second initialization control line GBL may extend through the first to third pixel circuits PC1, PC2, and PC3 along the first direction (e.g., +x direction). The second initialization control line GBL may include a second initialization gate electrode G7 of a second initialization transistor T7 and a bias gate electrode G8 of a bias transistor T8 of each of the first to third pixel circuits PC1, PC2, and PC3. The second initialization semiconductor layer A7 may include a channel region overlapping the second initialization gate electrode G7, and a source region and a drain region arranged on both sides of the channel region. The bias semiconductor layer A8 may include a channel region overlapping the bias gate electrode G8, and a source region and a drain region arranged on both sides of the channel region.

According to some embodiments, in a plan view, the second initialization control line GBL may intersect the first-2 branch portion BML1b (see FIG. 10) of the first blocking metal portion BML1 and the second-2 branch portion BML2b (see FIG. 10) of the second blocking metal portion BML2, and may be spaced apart from the third blocking metal portion BML3.

The driving transistor T1 may include the driving semiconductor layer A1 and the driving gate electrode G1. The data write transistor T2 may include the data write semiconductor layer A2 and the data write gate electrode G2. The operation control transistor T5 may include the operation control semiconductor layer A5 and the operation control gate electrode G5. The emission control transistor T6 may include the emission control semiconductor layer A6 and the emission control gate electrode G6. The second initialization transistor T7 may include the second initialization semiconductor layer A7 and the second initialization gate electrode G7.

The second gate insulating layer 113 (see FIG. 5) may be located on the first conductive layer 1200.

Referring to FIG. 13, a second conductive layer 1300 may be located on the first conductive layer 1200 (see FIG. 12). For example, the second gate insulating layer 113 (see FIG. 5) may be located on the first conductive layer 1200 (see FIG. 12), and the second conductive layer 1300 may be located on the second gate insulating layer 113 (see FIG. 5). The second conductive layer 1300 may include a second conductive pattern 1310, a first conductive line 1320, and a second conductive line 1330. The second conductive pattern 1310, the first conductive line 1320, and the second conductive line 1330 may be located on a same layer (e.g., the second gate insulating layer 113 (see FIG. 5)).

The second conductive pattern 1310, the first conductive line 1320, and the second conductive line 1330 may include a same material. Each of the second conductive pattern 1310, the first conductive line 1320, and the second conductive line 1330 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed as a single layer or multiple layers including the aforementioned materials.

The second conductive pattern 1310 may be arranged to overlap the first conductive pattern 1210. The second conductive pattern 1310 is a horizontal driving voltage line having a voltage level of a driving voltage and may extend along the first direction (e.g., the +x direction) to pass through the first to third pixel circuits PC1, PC2, and PC3.

According to some embodiments, the second conductive pattern 1310 may include first portions 1311, which respectively overlap the first conductive patterns 1210 arranged in the first to third pixel circuits PC1, PC2, and PC3, and second portions 1312 extending along the first direction (e.g., the +x direction) to connect the first portions 1311 located in the first to third pixel circuits PC1, PC2, and PC3. The second conductive pattern 1310 may include an opening 1310OP having closed-shaped.

The first conductive pattern 1210 arranged in each of the first pixel circuit PC1, the second pixel circuit PC2, and the third pixel circuit PC3 may correspond to the lower electrode CE1 of the first capacitor Cst. Each of the first portions 1311 of the second conductive pattern 1310 arranged in each of the first to third pixel circuits PC1, PC2, and PC3 may correspond to the upper electrode CE2 of the first capacitor Cst.

Referring to FIGS. 10 and 13, the second conductive pattern 1310 may overlap the blocking metal layer BML. The first portions 1311 of the second conductive pattern 1310 may overlap the first main portion BML1m of the first blocking metal portion BML1, the second main portion BML2m of the second blocking metal portion BML2, and the third main portion BML3m of the third blocking metal portion BML3, respectively. The second portions 1312 of the second conductive pattern 1310 may overlap the first-3 branch portion BML1c of the first blocking metal portion BML1, the second-3 branch portion BML2c of the second blocking metal portion BML2, and the third-2 branch portion BML3c of the third blocking metal portion BML3, respectively.

Each of the first conductive line 1320 and the second conductive line 1330 may extend through the first to third pixel circuits PC1, PC2, and PC3 along the first direction (e.g., the x direction). The first conductive line 1320 may include the lower compensation gate electrode G3a of the compensation transistor T3 of each of the first to third pixel circuits PC1, PC2, and PC3. The compensation scan signal GC (see FIG. 4) may be transmitted to the first conductive line 1320. The second conductive line 1330 may include a lower first initialization gate electrode G4a of the first initialization transistor T4 of each of the first to third pixel circuits PC1, PC2, and PC3. The first initialization control signal GI (see FIG. 4) may be transmitted to the second conductive line 1330.

The first interlayer insulating layer 114 (see FIG. 5) may be located on the second conductive layer 1300.

Referring to FIG. 14, a second semiconductor layer may be located on the second conductive layer 1300 (see FIG. 13). For example, the first interlayer insulating layer 114 (see FIG. 5) may be located on the second conductive layer 1300 (see FIG. 13), and the second semiconductor layer may be located on the first interlayer insulating layer 114 (see FIG. 5). The second semiconductor layer may include a third semiconductor pattern 1410.

The third semiconductor pattern 1410 may be arranged in each of the first to third pixel circuits PC1, PC2, and PC3 and may have an isolated shape. The third semiconductor pattern 1410, in a plan view, may be arranged to intersect the first conductive line 1320 and the second conductive line 1330. The third semiconductor pattern 1410 may include a portion overlapping the first conductive line 1320 and corresponding to the compensation semiconductor layer A3. The third semiconductor pattern 1410 may include a portion overlapping the second conductive line 1330 and corresponding to the first initialization semiconductor layer A4.

The second semiconductor layer (e.g., the third semiconductor pattern 1410) may include an oxide semiconductor material. For example, the third semiconductor pattern 1410 may include an oxide of at least one material selected from indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the third semiconductor pattern 1410 may include InSnZnO (ITZO), InGaZnO (IGZO), or the like. An oxide semiconductor has a wide band gap (e.g., 3.1 eV or about 3.1 eV), high carrier mobility, and a low leakage current, and thus, even when a driving time is long, a voltage drop is not large. Accordingly, a luminance change according to the voltage drop may not be large even during a low frequency operation.

The third gate insulating layer 115 (see FIG. 5) may be located on the third semiconductor pattern 1410.

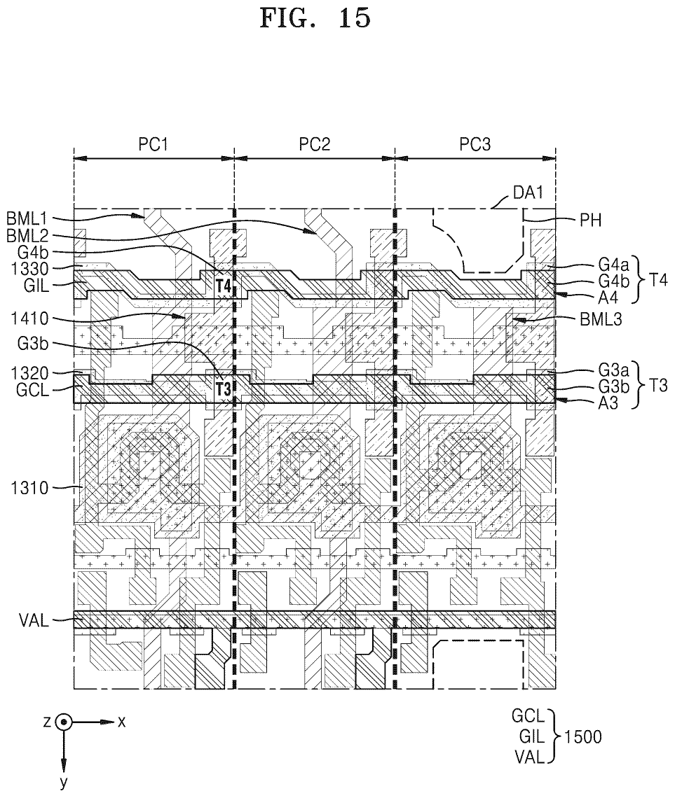

Referring to FIG. 15, a third conductive layer 1500 may be located on the third semiconductor pattern 1410. For example, the third gate insulating layer 115 (see FIG. 5) may be located on the third semiconductor pattern 1410, and the third conductive layer 1500 may be located on the third gate insulating layer 115 (see FIG. 5).

The third conductive layer 1500 may include the compensation scan line GCL, the first initialization control line GIL, and the second initialization voltage line VAL. Each of the compensation scan line GCL, the first initialization control line GIL, and the second initialization voltage line VAL may be located on the third gate insulating layer 115 (see FIG. 5).

As an example, the third gate insulating layers 115 (see FIG. 5) located below each of the compensation scan line GCL, the first initialization control line GIL, and the second initialization voltage line VAL as described above with reference to FIG. 5 may be separated from each other, but the disclosure is not limited thereto. According to some embodiments, the third gate insulating layers 115 (see FIG. 5) located below each of the compensation scan line GCL, the first initialization control line GIL, and the second initialization voltage line VAL may be integrally connected.

The compensation scan line GCL, the first initialization control line GIL, and the second initialization voltage line VAL may include a same material. Each of the compensation scan line GCL, the first initialization control line GIL, and the second initialization voltage line VAL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed as a single layer or multiple layers including the aforementioned material.

Each of the compensation scan line GCL, the first initialization control line GIL, and the second initialization voltage line VAL may extend through the first to third pixel circuits PC1, PC2, and PC3 along the first direction (e.g., the +x direction).

In a plan view, each of the compensation scan line GCL and the first initialization control line GIL may intersect the third semiconductor pattern 1410. Each of the compensation scan line GCL and the first initialization control line GIL may overlap the third semiconductor pattern 1410 and may include a gate electrode. The compensation scan line GCL may include the upper compensation gate electrode G3b of each of the first to third pixel circuits PC1, PC2, and PC3. The upper compensation gate electrode G3b may overlap a portion of the third semiconductor pattern 1410, for example, the compensation semiconductor layer A3. The first initialization control line GIL may include an upper first initialization gate electrode G4b of each of the first to third pixel circuits PC1, PC2, and PC3. The upper first initialization gate electrode G4b may overlap a portion of the third semiconductor pattern 1410, for example, the first initialization semiconductor layer A4.

The compensation semiconductor layer A3 may include a channel region overlapping the compensation scan line GCL, and a source region and a drain region arranged on both sides of the aforementioned channel region. The first initialization semiconductor layer A4 may include a channel region overlapping the first initialization control line GIL, and a source region and a drain region arranged on both sides of the aforementioned channel region.

The compensation transistor T3 may include a compensation semiconductor layer A3, the lower compensation gate electrode G3a located below the compensation semiconductor layer A3, and the upper compensation gate electrode G3b located above the compensation semiconductor layer A3. The first initialization transistor T4 may include the first initialization semiconductor layer A4, the lower first initialization gate electrode G4a located below the first initialization semiconductor layer A4, and the upper first initialization gate electrode G4b located above the first initialization semiconductor layer A4.

Referring to FIGS. 10 and 15, in a plan view, the first initialization control line GIL may intersect the first-1 branch portion BML1a of the first blocking metal portion BML1 and the second-1 branch portion BML2a of the second blocking metal portion BML2, and may be spaced apart from the third-1 branch portion BML3a of the third blocking metal portion BML3. In other words, the first initialization control line GIL may not overlap the third-1 branch portion BML3a of the third blocking metal portion BML3. In a plan view, the first initialization control line GIL may be spaced apart from the hole area PH. In other words, the first initialization control line GIL may not overlap the hole area PH.

The second interlayer insulating layer 116 (see FIG. 5) may be located on the third conductive layer 1500.

Referring to FIG. 16, a fourth conductive layer 1600 may be located on the third conductive layer 1500 (see FIG. 15). For example, the second interlayer insulating layer 116 (see FIG. 5) may be located on the third conductive layer 1500 (see FIG. 15), and the fourth conductive layer 1600 may be located on the second interlayer insulating layer 116 (see FIG. 5). The fourth conductive layer 1600 may include a first connection electrode 1610, a second connection electrode 1620, a third connection electrode 1630, a fourth connection electrode 1640, a fifth connection electrode 1650, a first pixel connection electrode 1660, a sixth connection electrode 1670, the first initialization voltage line VIL, and the bias voltage line VOL. The first connection electrode 1610, the second connection electrode 1620, the third connection electrode 1630, the fourth connection electrode 1640, the fifth connection electrode 1650, the first pixel connection electrode 1660, the sixth connection electrode 1670, the first initialization voltage line VIL, and the bias voltage line VOL may be located on a same layer (e.g., the second interlayer insulating layer 116 (see FIG. 5)).

The first connection electrode 1610, the second connection electrode 1620, the third connection electrode 1630, the fourth connection electrode 1640, the fifth connection electrode 1650, the first pixel connection electrode 1660, the sixth connection electrode 1670, the first initialization voltage line VIL, and the bias voltage line VOL may include a same material. Each of the first connection electrode 1610, the second connection electrode 1620, the third connection electrode 1630, the fourth connection electrode 1640, the fifth connection electrode 1650, the first pixel connection electrode 1660, the sixth connection electrode 1670, the first initialization voltage line VIL, and the bias voltage line VOL may include one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

Each of the first connection electrode 1610, the second connection electrode 1620, the third connection electrode 1630, the fourth connection electrode 1640, the fifth connection electrode 1650, the sixth connection electrode 1670, and the first pixel connection electrode 1660 may have an isolated shape. The first connection electrode 1610, the second connection electrode 1620, the third connection electrode 1630, the fourth connection electrode 1640, the fifth connection electrode 1650, the sixth connection electrode 1670, and the first pixel connection electrode 1660 may be arranged in each of the first to third pixel circuits PC1, PC2, and PC3. According to some embodiments, the sixth connection electrode 1670 arranged in the first pixel circuit PC1 may be provided integrally with the sixth connection electrode 1670 arranged in the third pixel circuit PC3 of the adjacent row.

The first connection electrode 1610 may electrically connect the first conductive pattern 1210 (see FIG. 12) and the third semiconductor pattern 1410 (see FIG. 14). The first connection electrode 1610 may be electrically connected to the first conductive pattern 1210 (see FIG. 12) through a first-1 contact hole CNT1a. The first connection electrode 1610 may be electrically connected to the third semiconductor pattern 1410 (for example, the compensation semiconductor layer A3 of a compensation transistor T3, see FIG. 14) through a first-2 contact hole CNT1b. The first connection electrode 1610 may electrically connect the driving gate electrode G1 (see FIG. 12) of the driving transistor T1 and the compensation semiconductor layer A3 (see FIG. 14) of the compensation transistor T3. The first connection electrode 1610 may electrically connect the first capacitor Cst and the compensation transistor T3.

The second connection electrode 1620 may be electrically connected to the first semiconductor pattern 1110 (see FIG. 11) through a second contact hole CNT2. For example, the second connection electrode 1620 corresponding to the first pixel circuit PC1 may be electrically connected to a first data line DL1 described below with reference to FIG. 17. In other words, the second connection electrode 1620 corresponding to the first pixel circuit PC1 may transmit the data signal applied to the first data line DL1 to the data write semiconductor layer A2 (see FIG. 11) of the data write transistor T2 of the first pixel circuit PC1. For example, the second connection electrode 1620 corresponding to the second pixel circuit PC2 may be electrically connected to a second data line DL2 described below with reference to FIG. 17. For example, the second connection electrode 1620 corresponding to the third pixel circuit PC3 may be electrically connected to a third data line DL3 described later with reference to FIG. 17.

The third connection electrode 1630 may electrically connect the first semiconductor pattern 1110 (see FIG. 11) and the third semiconductor pattern 1410 (see FIG. 14). The third connection electrode 1630 may be electrically connected to the first semiconductor pattern 1110 (see FIG. 11) through a third-1 contact hole CNT3a. The third connection electrode 1630 may be electrically connected to the third semiconductor pattern 1410 (see FIG. 14) through a third-2 contact hole CNT3b. The third connection electrode 1630 may electrically connect the driving semiconductor layer A1 (see FIG. 11) of the driving transistor T1 and the compensation semiconductor layer A3 (see FIG. 14) of the compensation transistor T3. The third connection electrode 1630 may electrically connect the emission control semiconductor layer A6 (see FIG. 11) of the emission control transistor T6 and the compensation semiconductor layer A3 (see FIG. 14) of the compensation transistor T3.

The fourth connection electrode 1640 may be electrically connected to the second conductive pattern 1310 (see FIG. 13) through a fourth-1 contact hole CNT4a. The fourth connection electrode 1640 may be electrically connected to the first semiconductor pattern 1110 (see FIG. 11) through a fourth-2 contact hole CNT4b.

The fourth connection electrode 1640 corresponding to the first pixel circuit PC1 may be electrically connected to a first driving voltage line PL1 described below. The fourth connection electrode 1640 corresponding to the second pixel circuit PC2 may be electrically connected to a second driving voltage line PL2 described below. The fourth connection electrode 1640 corresponding to the third pixel circuit PC3 may be electrically connected to a third driving voltage line PL3 described below. The fourth connection electrode 1640 may transmit the driving voltage ELVDD (see FIG. 4) of the driving voltage line PL (see FIG. 17) to the second conductive pattern 1310 (see FIG. 13) and the first semiconductor pattern 1110 (see FIG. 11). For example, the fourth connection electrode 1640 may transmit the driving voltage ELVDD (see FIG. 4) to the first capacitor Cst and the operation control semiconductor layer A5 (see FIG. 11) of the operation control transistor T5.

The fifth connection electrode 1650 may electrically connect the first semiconductor pattern 1110 (see FIG. 11) and the second semiconductor pattern 1120 (see FIG. 11). The fifth connection electrode 1650 may be electrically connected to the first semiconductor pattern 1110 (see FIG. 11) through a fifth-1 contact hole CNT5a. The fifth connection electrode 1650 may be electrically connected to the second semiconductor pattern 1120 (see FIG. 11) through a fifth-2 contact hole CNT5b. The fifth connection electrode 1650 may electrically connect the operation control semiconductor layer A5 (see FIG. 11) of the operation control transistor T5 formed along the first semiconductor pattern 1110 (see FIG. 11) and the bias semiconductor layer (A8, see FIG. 11) of the bias transistor T8 formed along the second semiconductor pattern (1120, see FIG. 11).

The first pixel connection electrode 1660 may include a first-1 pixel connection electrode 1660a, a first-2 pixel connection electrode 1660b, and a first-3 pixel connection electrode 1660c respectively arranged in the first to third pixel circuits PC1, PC2, and PC3.

The first pixel connection electrode 1660 may be electrically connected to the first semiconductor pattern 1110 (see FIG. 11) through a sixth contact hole CNT6. For example, the first-1 pixel connection electrode 1660a may be electrically connected to the first semiconductor pattern 1110 (see FIG. 11) corresponding to the first pixel circuit PC1 through the sixth contact hole CNT6. The first pixel connection electrode 1660 may be electrically connected to the emission control semiconductor layer A6 (see FIG. 11) of the emission control transistor T6 (see FIG. 9) and/or the second initialization semiconductor layer (A7, see FIG. 11) of the second initialization transistor T7.

The sixth connection electrode 1670 may electrically connect the second initialization voltage line VAL (see FIG. 15) and the first semiconductor pattern 1110 (see FIG. 11). The sixth connection electrode 1670 may be electrically connected to the first semiconductor pattern 1110 (see FIG. 11) through a seventh-1 contact hole CNT7a. The sixth connection electrode 1670 may be electrically connected to the second initialization voltage line VAL (see FIG. 15) through a seventh-2 contact hole CNT7b. The second initialization voltage Vaint (see FIG. 4) of the second initialization voltage line VAL (see FIG. 15) may be transmitted to the second initialization semiconductor layer A7 (see FIG. 11) of the second initialization transistor T7 by the sixth connection electrode 1670.

The first initialization voltage line VIL may extend through the first to third pixel circuits PC1, PC2, and PC3 along the first direction (e.g., the +x direction). The first initialization voltage line VIL may include a first portion VILa and a second portion VILb.

In a plan view, the first portion VILa of the first initialization voltage line VIL may intersect a portion of the blocking metal layer BML (see FIG. 10). For example, in a plan view, the first portion VILa of the first initialization voltage line VIL may intersect the first-1 branch portion BML1a (see FIG. 10) of the first blocking metal portion BML1 and the second-1 branch portion BML2a (see FIG. 10) of the second blocking metal portion BML2. According to some embodiments, the first portion VILa of the first initialization voltage line VIL may extend in a straight line along the first direction (e.g., the +x direction), in a plan view.

In a plan view, the second portion VILb of the first initialization voltage line VIL may be spaced apart from the blocking metal layer BML (see FIG. 10). For example, in a plan view, the second portion VILb of the first initialization voltage line VIL may be spaced apart from the third-1 branch portion BML3a (see FIG. 10) of the third blocking metal portion BML3. In other words, the second portion VILb of the first initialization voltage line VIL may not overlap the third-1 branch portion BML3a (see FIG. 10) of the third blocking metal portion BML3. In a plan view, the second portion VILb of the first initialization voltage line VIL may be curved at least partially along the perimeter of the hole area PH. In a plan view, the second portion VILb of the first initialization voltage line VIL may be spaced from the hole area PH.

The first initialization voltage line VIL may be electrically connected to the third semiconductor pattern 1410 (see FIG. 14) through an eighth contact hole CNT8. The first initialization voltage line VIL may be electrically connected to the first initialization semiconductor layer A4 of the first initialization transistor T4 through the eighth contact hole CNT8.

The bias voltage line VOL may extend through the first to third pixel circuits PC1, PC2, and PC3 along the first direction (e.g., the +x direction). The bias voltage line VOL may be electrically connected to the second semiconductor pattern 1120 (see FIG. 11) through a ninth contact hole CNT9. The bias voltage line VOL may be electrically connected to the bias semiconductor layer A8 (see FIG. 11) of the bias transistor T8 via the ninth contact hole CNT9.

The first via insulating layer 121 (see FIG. 5) may be located on the fourth conductive layer 1600.

Referring to FIG. 17, a fifth conductive layer 1700 may be located on the fourth conductive layer 1600 (see FIG. 16). For example, the first via insulating layer 121 (see FIG. 5) may be located on the fourth conductive layer 1600 (see FIG. 16), and the fifth conductive layer 1700 may be located on the first via insulating layer 121 (see FIG. 5). The fifth conductive layer 1700 may include a second pixel connection electrode 1710, the data line DL, and the driving voltage line PL. The second pixel connection electrode 1710, the data line DL, and the driving voltage line PL may be located on a same layer (e.g., the first via insulating layer 121 (see FIG. 5)).

The second pixel connection electrode 1710, the data line DL, and the driving voltage line PL may include a same material. Each of the second pixel connection electrode 1710, the data line DL, and the driving voltage line PL may include one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The data lines DL may include a first data line DL1, a second data line DL2, and a third data line DL3 arranged in the first to third pixel circuits PC1, PC2, and PC3, 1 respectively. Each of the first to third data lines DL1, DL2, and DL3 may extend along the second direction (+y direction). Each of the first to third data lines DL1, DL2, and DL3 may be electrically connected to a corresponding second connection electrode 1620 (see FIG. 16) through a tenth contact hole CNT10.

The driving voltage lines PL may include a first driving voltage line PL1, a second driving voltage line PL2, and a third driving voltage line PL3 arranged in the first to third pixel circuits PC1, PC2, and PC3, respectively. Each of the first to third driving voltage lines PL1, PL2, and PL3 may extend along the second direction (+y direction). Each of the first to third driving voltage lines PL1, PL2, and PL3 may be electrically connected to a corresponding fourth connection electrode 1640 (see FIG. 16) through an eleventh contact hole CNT11. Shapes of the first to third driving voltage lines PL1, PL2, and PL3 may be differ from each other.

The second pixel connection electrode 1710 may be electrically connected to a corresponding first pixel connection electrode 1660 (see FIG. 16) through a 12th contact hole CNT12. For example, a second-1 pixel connection electrode 1710a may be electrically connected to the first-1 pixel connection electrode 1660a. For example, a second-2 pixel connection electrode 1710b may be electrically connected to the first-2 pixel connection electrode 1660b. For example, a second-3 pixel connection electrode 1710c may be electrically connected to the first-3 pixel connection electrode 1660c.

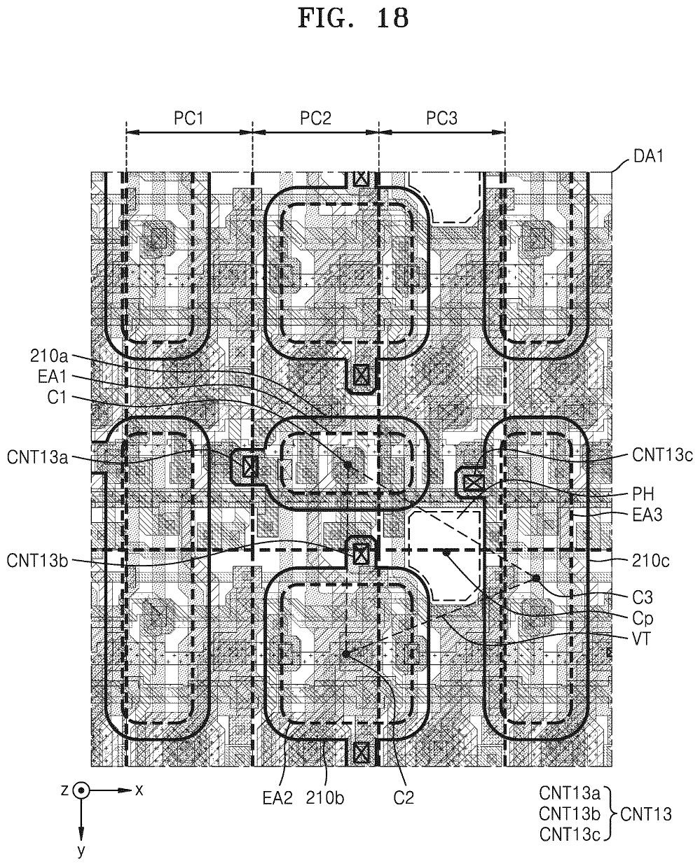

The second pixel connection electrode 1710 may be electrically connected to pixel electrodes described below through a 13th contact hole CNT13. For example, the second-1 pixel connection electrode 1710a may be electrically connected to the first pixel electrode 210a (see FIG. 18). For example, the second-2 pixel connection electrode 1710b may be electrically connected to the second pixel electrode 210b (see FIG. 18). For example, the second-3 pixel connection electrode 1710c may be electrically connected to the third pixel electrode 210c (see FIG. 18).

The second via insulating layer 123 (see FIG. 5) may be located on the fifth conductive layer 1700.

FIG. 18 is a plan view of an arrangement of the light-emitting areas of the light-emitting elements of the first pixel circuit PC1, the second pixel circuit PC2, and the third pixel circuit PC3 and the hole areas PH, in the first display area DA1 of FIG. 9.

Referring to FIG. 18, the first pixel electrode 210a, the second pixel electrode 210b, and the third pixel electrode 210c may be located on the fifth conductive layer 1700. For example, the second via insulating layer 123 (see FIG. 5) may be located on the fifth conductive layer 1700, and the first pixel electrode 210a, the second pixel electrode 210b, and the third pixel electrode 210c may be located on the second via insulating layer 123 (see FIG. 5).

The first pixel electrode 210a, the second pixel electrode 210b, and the third pixel electrode 210c may be electrically connected to the first pixel circuit PC1, the second pixel circuit PC2, and the third pixel circuit PC3, respectively, through a 13th contact hole CNT13.

For example, the first pixel electrode 210a may be electrically connected to the second-1 pixel connection electrode 1710a through a 13th-1 contact hole CNT13a. Accordingly, the first pixel electrode 210a may be electrically connected to the emission control semiconductor layer A6 (see FIG. 11) of the emission control transistor T6 (see FIG. 12) and/or the second initialization semiconductor layer A7 (see FIG. 11) of the second initialization transistor T7 (see FIG. 12) in the first pixel circuit PC1.

For example, the second pixel electrode 210b may be electrically connected to the second-2 pixel connection electrode 1710b through a 13th-2 contact hole CNT13b. Accordingly, the second pixel electrode 210b may be electrically connected to the emission control semiconductor layer A6 (see FIG. 11) of the emission control transistor T6 (see FIG. 12) and/or the second initialization semiconductor layer A7 (see FIG. 11) of the second initialization transistor T7 (see FIG. 12) in the second pixel circuit PC2.

For example, the third pixel electrode 210c may be electrically connected to the second-3 pixel connection electrode 1710c through a 13th-3 contact hole CNT13c. Accordingly, the third pixel electrode 210c may be electrically connected to the emission control semiconductor layer A6 (see FIG. 11) of the emission control transistor T6 (see FIG. 12) and/or the second initialization semiconductor layer A7 (see FIG. 11) of the second initialization transistor T7 (see FIG. 12) in the third pixel circuit PC3.

The first light-emitting area EA1, the second light-emitting area EA2, and the third light-emitting area EA3 may be defined by pixel openings of the pixel defining layer 130 (see FIG. 8) that overlap the first pixel electrode 210a, the second pixel electrode 210b, and the third pixel electrode 210c, respectively.

As illustrated in FIG. 18, the hole area PH may be located between the first light-emitting area EA1, the second light-emitting area EA2, and the third light-emitting area EA3 in the first display area DA1.

One or more embodiments of the disclosure may be formed so that circuit elements constituting the first to third pixel circuits PC1, PC2, and PC3 and/or wires electrically connected to the first to third pixel circuits PC1, PC2, and PC3 are not arranged within the imaginary triangle VT defined by connecting the center C1 of the first light-emitting area EA1, the center C2 of the second light-emitting area EA2, and the center C3 of the third light-emitting area EA3, in a plan view. Accordingly, the center Cp of the hole area PH may be located within the imaginary triangle VT defined by connecting the center C1 of the first light-emitting area EA1, the center C2 of the second light-emitting area EA2, and the center C3 of the third light-emitting area EA3.

According to some embodiments, by forming the length of the third-1 branch portion BML3a of the blocking metal layer BML (see FIG. 10) relatively smaller than the first-1 branch portion BML1a and the second-1 branch portion BML2a, the center Cp of the hole area PH may be formed to be located within the imaginary triangle VT defined by connecting the center C1 of the first light-emitting area EA1, the center C2 of the second light-emitting area EA2, and the center C3 of the third light-emitting area EA3.

According to some embodiments, the first initialization voltage line VIL (see FIG. 16) includes the first portion VILa (see FIG. 16) extending in a straight shape and the second portion VILb (see FIG. 16) including at least a portion that is curved, so that the center Cp of the hole area PH may be formed to be located within the imaginary triangle VT defined by connecting the center C1 of the first light-emitting area EA1, the center C2 of the second light-emitting area EA2, and the center C3 of the third light-emitting area EA3.

According to some embodiments, by forming the hole area PH defined by the pixel defining layer 130 (see FIG. 5) including a light-blocking insulating layer material to be located between the first to third light-emitting areas EA1, EA2, and EA3, a transmittance of the electronic device 1 (see FIG. 2) may be increased, thereby increasing the recognition rate of the component 40 (see FIG. 2) located under the hole area PH.

The display panel and the electronic device including the same according to some embodiments of the present disclosure may secure a transmittance of the area where the components are placed by preventing or reducing the circuit elements of the pixel circuits and/or the wires electrically connected to the pixel circuits from overlapping the area where the components are placed. However, the scope of embodiments according to the present disclosure is not limited by such effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
a first pixel circuit, a second pixel circuit, and a third pixel circuit each including a driving transistor and a capacitor on a substrate, and arranged along a first direction;
a first light-emitting element, a second light-emitting element, and a third light-emitting element, electrically connected to the first pixel circuit, the second pixel circuit, and the third pixel circuit, respectively; and
a pixel defining layer including a first pixel opening defining a first light-emitting area of the first light-emitting element, a second pixel opening defining a second light-emitting area of the second light-emitting element, a third pixel opening defining a third light-emitting area of the third light-emitting element, and an opening defining a hole area,
wherein, in a plan view, the first light-emitting area and the second light-emitting area are arranged along a second direction perpendicular to the first direction, and the third light-emitting area is arranged along the first direction from each of the first light-emitting area and the second light-emitting area,
wherein, in the plan view, the hole area is spaced apart from circuit elements constituting the first pixel circuit, wires electrically connected to the first pixel circuit, circuit elements constituting the second pixel circuit, wires electrically connected to the second pixel circuit, circuit elements constituting the third pixel circuit, and wires electrically connected to the third pixel circuit, and
wherein, in the plan view, a center of the hole area is located within an imaginary triangle defined by connecting a center of the first light-emitting area, a center of the second light-emitting area, and a center of the third light-emitting area.

2. The display panel of claim 1, further comprising
a blocking metal layer between an upper surface of the substrate and the driving transistor of the first pixel circuit, between the upper surface of the substrate and the driving transistor of the second pixel circuit, and between the upper surface of the substrate and the driving transistor of the third pixel circuit,
wherein the blocking metal layer comprises:
a first blocking metal portion including a first main portion overlapping a channel region of the driving transistor of the first pixel circuit and a first branch portion connected to the first main portion and extending in a third direction opposite to the second direction from the first main portion;
a second blocking metal portion including a second main portion overlapping a channel region of the driving transistor of the second pixel circuit and a second branch portion connected to the second main portion and extending in the third direction from the second main portion; and
a third blocking metal portion including a third main portion overlapping a channel region of the driving transistor of the third pixel circuit and a third branch portion connected to the third main portion and extending in the third direction from the third main portion,
wherein a length of the third branch portion along the third direction is less than a length of the first branch portion along the third direction and a length of the second branch portion along the third direction.

3. The display panel of claim 2, further comprising a first initialization control line extending in the first direction,
wherein, in the plan view, the first initialization control line intersects the first branch portion and the second branch portion and is spaced apart from the third branch portion and the hole area.

4. The display panel of claim 3, wherein
each of the first pixel circuit, the second pixel circuit, and the third pixel circuit further comprises a first initialization transistor including a first initialization semiconductor layer and a first initialization gate electrode, and
the first initialization control line includes the first initialization gate electrode of each of the first pixel circuit, the second pixel circuit, and the third pixel circuit.

5. The display panel of claim 4, wherein the first initialization semiconductor layer of the first initialization transistor is on a different layer from a driving semiconductor layer of the driving transistor of each of the first pixel circuit, the second pixel circuit, and the third pixel circuit.

6. The display panel of claim 4, further comprising a first initialization voltage line extending in the first direction and electrically connected to the first initialization semiconductor layer of the first initialization transistor of each of the first pixel circuit, the second pixel circuit, and the third pixel circuit.

7. The display panel of claim 6, wherein
the first initialization voltage line includes a first portion and a second portion, the first portion intersecting the first branch portion and the second branch portion in the plan view and the second portion being adjacent to the hole area in the plan view, and
at least a part of the second portion of the first initialization voltage line is curved along a perimeter of the hole area in the plan view.

8. The display panel of claim 7, wherein
the first portion extends in a straight line along the first direction in the plan view.

9. The display panel of claim 1, wherein
the pixel defining layer includes a light-blocking insulating layer.

10. The display panel of claim 1, wherein
each of the first light-emitting element, the second light-emitting element, and the third light-emitting element comprises:
a pixel electrode;
an emission layer on the pixel electrode; and
a counter electrode on the emission layer,
wherein the counter electrode is integrally provided corresponding to the first light-emitting element, the second light-emitting element, and the third light-emitting element and includes an opening corresponding to the hole area.

11. A display panel comprising:
a first pixel circuit, a second pixel circuit, and a third pixel circuit each including a first transistor and a second transistor on a substrate and being adjacent along a first direction;
a first light-emitting element, a second light-emitting element, and a third light-emitting element, electrically connected to the first pixel circuit, the second pixel circuit, and the third pixel circuit, respectively; and
a pixel defining layer including a first pixel opening defining a first light-emitting area of the first light-emitting element, a second pixel opening defining a second light-emitting area of the second light-emitting element, a third pixel opening defining a third light-emitting area of the third light-emitting element, and an opening defining a hole area located between the first light-emitting area, the second light-emitting area, and the third light-emitting area,
wherein, in a plan view, the first light-emitting area and the second light-emitting area are arranged along a second direction perpendicular to the first direction, and the third light-emitting area is arranged along the first direction from each of the first light-emitting area and the second light-emitting area, and
wherein the first light-emitting area, the hole area, and the second light-emitting area are staggered along the second direction.

12. The display panel of claim 11, further comprising
a first initialization voltage line extending in the first direction and electrically connected to the second transistor of each of the first pixel circuit, the second pixel circuit, and the third pixel circuit,
wherein the first initialization voltage line includes a first portion and a second portion, the first portion extending in a straight line along the first direction in the plan view, and the second portion being at least partially curved along a perimeter of the hole area and spaced apart from the hole area in the plan view.

13. The display panel of claim 12, wherein
the first transistor includes a first semiconductor layer and a first gate electrode on the first semiconductor layer,
the second transistor includes a second semiconductor layer on the first gate electrode and a second gate electrode on the second semiconductor layer, and
the first initialization voltage line is electrically connected to the second semiconductor layer of the second transistor.

14. The display panel of claim 12, further comprising
a blocking metal layer between an upper surface of the substrate and the first transistor of the first pixel circuit, between the upper surface of the substrate and the first transistor of the second pixel circuit, and between the upper surface of the substrate and the first transistor of the third pixel circuit,
wherein, in the plan view, the first portion of the first initialization voltage line intersects a part of the blocking metal layer, and the second portion of the first initialization voltage line is spaced apart from the blocking metal layer.

15. The display panel of claim 14, wherein the blocking metal layer comprises:
a first blocking metal portion including a first main portion overlapping a channel region of the first transistor of the first pixel circuit and a first branch portion connected to the first main portion and extending in a third direction opposite to the second direction from the first main portion;
a second blocking metal portion including a second main portion overlapping a channel region of the first transistor of the second pixel circuit and a second branch portion connected to the second main portion and extending in the third direction from the second main portion; and
a third blocking metal portion including a third main portion overlapping a channel region of the first transistor of the third pixel circuit and a third branch portion connected to the third main portion and extending in the third direction from the third main portion,
wherein a length of the third branch portion along the third direction is less than a length of the first branch portion along the third direction and a length of the second branch portion along the third direction.

16. The display panel of claim 15, further comprising
a first initialization control line extending in the first direction,
wherein, in the plan view, the first initialization control line intersects the first branch portion and the second branch portion, and is spaced apart from the third branch portion and the hole area.

17. The display panel of claim 16, wherein the first initialization control line includes a second gate electrode of the second transistor of each of the first pixel circuit, the second pixel circuit, and the third pixel circuit.

18. The display panel of claim 11, wherein the pixel defining layer includes a light-blocking insulating layer.

19. The display panel of claim 11, wherein each of the first light-emitting element, the second light-emitting element, and the third light-emitting element comprises:
a pixel electrode;
an emission layer on the pixel electrode; and
a counter electrode on the emission layer,
wherein the counter electrode is integrally provided corresponding to the first light-emitting element, the second light-emitting element, and the third light-emitting element, and includes an opening corresponding to the hole area.

20. An electronic device comprising:
a display panel; and
a component on a lower surface of the display panel,
wherein the display panel comprises:
a first pixel circuit, a second pixel circuit, and a third pixel circuit each including a driving transistor and a capacitor on a substrate, and being adjacent along a first direction;
a first light-emitting element, a second light-emitting element, and a third light-emitting element, electrically connected to the first pixel circuit, the second pixel circuit, and the third pixel circuit, respectively; and
a pixel defining layer including a first pixel opening defining a first light-emitting area of the first light-emitting element, a second pixel opening defining a second light-emitting area of the second light-emitting element, a third pixel opening defining a third light-emitting area of the third light-emitting element, and an opening defining a hole area,
wherein, in a plan view, the first light-emitting area and the second light-emitting area are arranged along a second direction perpendicular to the first direction, and the third light-emitting area is arranged along the first direction from each of the first light-emitting area and the second light-emitting area,
wherein, in the plan view, the hole area is spaced apart from circuit elements constituting the first pixel circuit, wires electrically connected to the first pixel circuit, circuit elements constituting the second pixel circuit, wires electrically connected to the second pixel circuit, circuit elements constituting the third pixel circuit, and wires electrically connected to the third pixel circuit,
wherein, in the plan view, a center of the hole area is within an imaginary triangle defined by connecting a center of the first light-emitting area, a center of the second light-emitting area, and a center of the third light-emitting area, and
wherein the component overlaps the hole area.
